(19) United States
(12) Patent Application Publication
(10) Pub. No.: US 2014/0144503 A1
(43) Pub. Date: May 29, 2014

(54) POLYMER SHEET FOR SOLAR CELL, AND SOLAR CELL MODULE

(71) Applicant: FUJIFILM Corporation, Tokyo (JP)

(72) Inventors: Hitoshi YAMADA, Shizuoka (JP); Kiyokazu HASHIMOTO, Shizuoka (JP); Ryuta TAKEGAMI, Shizuoka (JP); Kazumori MINAMI, Shizuoka (JP)

(73) Assignee: FUJIFILM Corporation, Tokyo (JP)

(21) Appl. No.: 14/151,446

(22) Filed: Jan. 9, 2014

Related U.S. Application Data
(63) Continuation of application No. PCT/JP2012/068121, filed on Jul. 17, 2012.

(30) Foreign Application Priority Data
Jul. 14, 2011 (JP) 2011-155781

(51) Int. Cl. H01L 31/048; H01L 31/18

(52) U.S. Cl. CPC H01L 31/0487; H01L 31/18
USPC 136/256; 156/229

(57) ABSTRACT

A polymer sheet for a solar cell, including: a first polymer layer; a second polymer layer; and a polymer support, arranged in this order, wherein the first polymer layer includes a polymer selected from the group consisting of a fluorine polymer and a silicone polymer, the first polymer layer contacts the second polymer layer, and a roughness (Rz) of an interface between the first polymer layer and the second polymer layer is in a range of from 0.2 μm to 3.0 μm.

### CROSS-REFERENCE TO RELATED APPLICATIONS

This application is a continuation application of International Application No. PCT/JP/2012/068121, filed Jul. 17, 2012, which is incorporated herein by reference. Further, this application claims priority from Japanese Patent Application No. 2011-155781, filed Jul. 14, 2011, which is incorporated herein by reference.

### TECHNICAL FIELD

The present invention relates to a polymer sheet for a solar cell and a solar cell module.

### BACKGROUND ART

A solar cell module generally has a structure in which a sealant, a solar cell element, a sealant, and a backsheet are layered in this order on a glass or a front sheet on which sunlight is incident. In particular, a solar cell element is, generally, configured by a structure in which a solar cell element is embedded by a resin (a sealant) such as an ethylene-vinyl acetate copolymer (EVA) and attached with a protective sheet for a solar cell thereon. As this protective sheet for the solar cell, a polyester film, particularly, a polyethylene terephthalate (PET) film has been conventionally used.

When a general PET film is used for a long period of time as a protective sheet for a solar cell, and among these, particularly a backsheet for a solar cell which is an outermost layer, separation is likely to occur on the solar cell. When the backsheet of a single layer of the PET film is placed under an environment to be exposed to wind and rain such as outdoors for a long period of time, the separation is likely to occur between the backsheet and the sealant such as an EVA. In view of addressing this problem in weather resistance, a layered body type backsheet on which a weather resistance film is attached onto the side of the outermost layer of a base film such as a PET has been conventionally mainly used. The most used film among the attaching method-layered bodies was a fluorocarbon polymer film such as a polyvinyl fluoride film.

There were problems in which adhesion (the adhesive properties) of interlayer between a polyester film and a fluorocarbon polymer film was week in a case of using the fluorocarbon polymer film as a layered body type backsheet for the solar cell, and particularly, separation was likely to occur between layers, when used for long period of time. In this regard, in recent years, an applied type backsheet in which a composition that includes the fluorocarbon polymer is applied onto a PET base film has been developed (refer to Japanese Patent Application Laid-Open (JP-A) No. 2010-95640, JP-A No. 2010-53317, JP-A No. 2007-35694, International Publication Pamphlet No. WO 2008/143719 and JP-A No. 2010-053317). For example, a polymer sheet in which a polyethylene terephthalate support that has a specific thickness and a weather resistant layer which is a fluorine-containing polymer layer are layered by application is disclosed in JP-A No. 2010-53317 or the like.

On the other hand, in addition to the weather resistant layer, various other functional layers are also becoming to be layered on a backsheet for a solar cell. For example, a method for improving power generation efficiency by layering a white layer to which light reflection performance is imparted by adding white inorganic fine particles such as titanium oxide to the backsheet so that the light which has passed through a cell without stopping to the cell by diffused reflection returns, or the like is described in JP-A No. 2003-060218. Further, in order to obtain high adhesive strength between a backsheet and an EVA sealant, there are cases in which a polymer layer such as an easy adhesive layer is provided on an outermost surface layer of the backsheet. A technique of providing a thermoadhesive layer on a white polyethylene terephthalate film is described in JP-A No. 2003-060218. The backsheet is formed to have a configuration in which various functional layers that have other functions are layered on a base polymer to impart the functions as described above thereto.

Method which intend making the base polymer itself be multi-layered are known. For example, a layered film that contains a polymer support that has a three-layer structure and a fluorocarbon resin is disclosed in JP-A No. 2010-95640. The polymer support that has the three-layer structure is used and the layer constitution is multi-layered in JP-A No. 2010-95640 described above.

### SUMMARY OF INVENTION

### Technical Problem

As described above, the protective sheet for the solar cell in which multilayering tends to progress is likely to increasingly cause a problem of insufficiency of adhesion between respective layers as the number of layering increases.

Further, in recent years, there is a demand for using a solar cell at harsh places such as outdoors from the viewpoint of further enhancing power generation efficiency of a solar cell, reducing cost by accumulating and setting up, or the like, and there is a demand for improving long term storage stability under a high temperature and high humidity environment corresponding to a long service life of the solar cell.

However, literatures described above examined nothing with regard to long term storage stability under a high temperature and high humidity environment.

Under such circumstances, by using a layered film described in JP-A No. 2010-53317 and a support that has a layered structure described in JP-A No. 2010-95640, the inventors examined adhesion thereof. As a result, although a problem hardly occurs to some extent as to adhesion of the interlayer of this layered film and the support that has the layered structure under a normal environment, in a case of using in an accelerated test that assumes the use outdoors or the like, the knowledge in which adhesion of the polymer interlayer with wet heat over time under a high temperature and high humidity environment was deteriorated was obtained. Therefore, it was understood that a conventional layered film and support that has the layered structure as described in prior art literatures described above such as JP-A No. 2010-95640 and JP-A No. 2010-53317 was still insufficient, from the viewpoint of long term storage stability under a high temperature and high humidity environment required for the solar cell in recent years. In particular, since the adhesive layers which are not suitable under a high wet heat environment increase as the number of layers increases, the adhesive layers tend to separate due to degradation over time, and it was understood that there was further room for improvement in a case of assuming a long service life.

Further improvement is required as to the adhesive properties of the interlayer in a case of providing a polymer layer that contains a polymer such as a fluorine polymer and a silicone polymer adjacent to other polymer layer, further.

The present invention was made in the light of the circumstances as described above. The present invention can provide a polymer sheet for a solar cell that has high adhesion between polymer layers provided on a support and excellent durability under a wet heat environment, and a solar cell module that includes the polymer sheet for the solar cell and that has stable power generation efficiency over a long period of time.

### Solution to Problem

Specific means for accomplishing for the problems described above is as below.

[1] A polymer sheet for a solar cell, comprising:

a first polymer layer;

a second polymer layer; and

a polymer support, arranged in this order,

wherein the first polymer layer comprises a polymer selected from the group consisting of a fluorine polymer and a silicone polymer,

the first polymer layer contacts the second polymer layer, and

a roughness (Rz) of an interface between the first polymer layer and the second polymer layer is in a range of from 0.2 μm to 3.0 μm.

[2] The polymer sheet according to [1], wherein the second polymer layer comprises a silicone polymer.

[3] The polymer sheet according to [1] or [2], wherein the second polymer layer comprises particles having a volume average particle diameter in a range of from 0.2 μm to 1.5 μm.

[4] The polymer sheet according to any one of [1] to [3], wherein the second polymer layer comprises particles having a volume average particle diameter in a range of from 0.3 μm to 0.6 μm.

[5] The polymer sheet according to any one of [1] to [4], wherein the second polymer layer comprises titanium dioxide particles.

[6] The polymer sheet according to any one of [1] to [5], wherein the first polymer layer and the second polymer layer are layers formed by coating.

[7] The polymer sheet according to any one of [1] to [6], wherein the first polymer layer is an outermost layer.

[8] The polymer sheet according to any one of [1] to [7], further comprising a terminal sealing agent in an amount of from 0.1% by mass to 10% by mass with respect to a total mass of the polymer that configures the polymer support.

[9] The polymer sheet according to any one of [1] to [8], wherein

the polymer support comprises fine particles that are inorganic particles or organic particles,

an average particle diameter of the fine particles is from 0.1 μm to 10 μm, and

a content of the fine particles is from 0% by mass to 50% by mass with respect to a total mass of the polymer support.

[10] A method of manufacturing the polymer sheet according to any one of [1] to [9], comprising:

forming a polymer support and an undercoat layer, including:
supplying an unstretched sheet that comprises a polymer that configures the polymer support,
stretching the unstretched sheet in a first direction,
applying a composition for forming an undercoat layer onto at least one surface of the sheet stretched in the first direction, and
stretching the sheet, to which the composition for forming an undercoat layer is applied, in a direction perpendicular to the first direction; and

disposing the second polymer layer and the first polymer layer, in this order, on the undercoat layer.

[11] A method of manufacturing the polymer sheet according to any one of [1] to [9], comprising treating a surface of the polymer support by a method selected from the group consisting of corona treatment, flame treatment and glow discharge treatment.

[12] A solar cell module comprising;

a front substrate on which sunlight is incident and which has transparency;

a cell structure part that is provided on one surface of the front substrate and includes a solar cell element and a sealant that seals the solar cell element; and

a backsheet provided on an opposite side to a side at which the front substrate of the cell structure part is located, is disposed so as to contact the sealant, and is the polymer sheet according to any one of [1] to [9].

### Advantageous Effects of Invention

According to the present invention, a polymer sheet for a solar cell that has high adhesion between polymer layers provided on a support and excellent durability under a wet heat environment, and a solar cell module that includes the polymer sheet for the solar cell and has stable power generation efficiency over a long period of time can be provided.

### BRIEF DESCRIPTION OF DRAWING

FIG. 1 is a schematic cross-sectional view that shows a configuration example of a solar cell module.

### DESCRIPTION OF EMBODIMENTS

Below, detailed description will be given of a protective sheet for a solar cell and a manufacturing method for the same in the present invention.

The description of the constituent components described below is sometimes given based on representative embodiments of the present invention, however, the present invention is not limited to such embodiments.

The notation of the numeric value range in the present specification signifies the range that includes the numeric value represented as the lower limit value of the numeric value range as the minimum value, and that includes the numeric value represented as the upper limit value as the maximum value.

In a case of mentioning of the quantity of a certain component in a composition, in a case where there are plural substances corresponding to the component in the composition, unless particularly otherwise defined, the quantity means the total amount of the plural substances that exist in the composition.

Not only a step which is independent, but also a step which is unable to be clearly distinguished from other steps is included in the term “step”, as long as it is a step which accomplishes the action desired therein.

<Polymer Sheet for Solar Cell>

A polymer sheet for a solar cell according to an embodiment of the present invention (hereinafter, also simply referred to as a “polymer sheet”) includes a first polymer layer that contains at least one selected from the group consisting of a fluorine polymer and a silicone polymer and that is on a polymer support and a second polymer layer contacting to the side of the polymer support of the first polymer layer, in which a roughness (Rz) of an interface between the first polymer layer and the second polymer layer is in a range from 0.2 μm to 3.0 μm.

The polymer sheet according to an embodiment of the present invention is suitably used as a backsheet that configures a solar cell power module.

It is possible to enhance adhesion between polymer layers and obtain excellent durability under a wet heat environment by increasing the interfacial area by imparting the roughness of a specific range to the interface between the first polymer layer and the second polymer layer.

“Rz”, which is an index for indicating a roughness of an interface between the first polymer layer and the second polymer layer, is defined by the following measurement method.

—Measurement Method of Rz—

Five points of observation parts on a cross-section which is obtained by cutting a polymer sheet to be measured vertically with respect to the plane surface thereof are selected as the interval of adjacent observation points being 3 cm. The cross-sections of these five points of observation parts are imaged with a magnifying power of 6,000 to 10,000 by using a scanning electron microscope (trade name: S4700, manufactured by Hitachi, Ltd.). In the obtained cross-section pictures of the five points, the length in which the difference between the maximum distance and the minimum distance from the interface between the polymer support and the second polymer layer to the interface between the second polymer layer and the first polymer layer is maximum is measured and the average value of the lengths in five points is regarded as Rz.

Rz is set in a range of from 0.2 μm to 3.0 μm. When Rz is 0.2 μm or more, the durability of adhesion between polymer layers provided on the support under a wet heat environment may increase. When Rz is 3.0 μm or less, since the first polymer layer has a sufficient thickness, the performance of the first polymer layer may be satisfied, sufficient adhesion between the first polymer layer and the second polymer layer may be ensured, and the durability in a wet heat environment may be increased.

Preferable examples of a method for regulating the roughness (Rz) of an interface between the first polymer layer and the second polymer layer to be in a range of from 0.2 μm to 3.0 μm include a method of making the second polymer layer contain particles that have a specific particle diameter and a method of layering the first polymer layer after transferring the roughness onto the second polymer layer by using a transfer roll with an unevenness.

In order to regulate Rz, as particles which can be contained in the second polymer layer, particles (hereinafter, referred to as “specific particles” as appropriate) having a volume average particle diameter of from 0.2 μm to 1.5 μm are preferable, and particles having a volume average particle diameter of from 0.3 μm to 0.6 μm are more preferable, from the viewpoint of being capable of enhancing adhesion between polymer layers provided on the support and having excellent durability under a wet heat environment.

The volume average particle diameter of specific particles is a value measured by using a laser diffraction/scattering grain size distribution measuring apparatus LA950 (manufacture by HORIBA Ltd.).

Specific particles may be inorganic particles or organic particles.

As inorganic particles which are specific particles, for example, titanium oxide (for example, titanium dioxide), particles of metallic oxide such as ITO and particles such as glass beads and colloidal silica are preferably included. As the inorganic particles, commercial products can be applied, and for example, TIPAQUE (registered trademark) CL 95, TIPAQUE (registered trademark) PF-691, TIPAQUE (registered trademark) CR-60-2 (hereinbefore, manufactured by ISHIHARA SANGYO KAISHA, LTD.)

As organic particles which are specific particles, for example, an acryl resin (for example, a polymethylmethacrylate resin (PMMA)) and polymer particles such as polystyrene are preferably included. As the organic particles, commercial products can be applied, and for example, MP-2000 (trade name, manufactured by Soken Chemical & Engineering Co., Ltd.), or the like is included.

The shape of specific particles is not particularly limited, and a spherical shape, a columnar shape, flaky powder, a hollow particle, a porous particle, an amorphous particle, a needle-shaped, and the like are included. A spherical shape is preferable, from the viewpoint of being able to stably regulate Rz.

In one embodiment, it is preferable that specific particles be inorganic particles which function as a white pigment, from the viewpoint of also functioning as a colored layer and enhancing adhesion as an entire polymer sheet under a wet heat environment by decreasing the number of layers. From these viewpoints, among specific particles, a titanium dioxide particle is particularly preferable.

In the second polymer layer, the content of specific particles contained to regulate Rz is preferably more than 0% by mass and 25% by mass or less, more preferably from 3% by mass to 20% by mass, and particularly preferably from 5% by mass to 10% by mass, with respect to the main binder of the second polymer layer. When the content of specific particles is 25% by mass or less, with respect to the main binder of the second polymer layer, it is possible to more successfully maintain the sheet of the second polymer layer. Here, the main binder in the second polymer layer is a binder in which the content is the largest among binders included in the second polymer layer.

Apart from the above, description will be given of a suitable aspect about the second polymer layer later.

Hereinafter, with regard to each constituent element in a polymer sheet, description will be given of the characteristics of a polymer support, a first polymer layer, a second polymer layer, a layer configuration and a polymer sheet in order in more detail.

(Polymer Support)

A polymer sheet according to one embodiment of the present invention includes a polymer support.

The polymer support is preferably a polymer support which is a single layer and has the thickness of 220 μm or more.

As a polymer that configures the polymer support (base), polyester, polyolefin such as polypropylene and polyethylene, a fluorocarbon polymer such as polyvinyl fluoride, and the like are included. Among these, polyester is preferable, and above all, polyethylene terephthalate is particularly preferable due to the point of dynamic characteristics and cost balance.

The carboxyl group content of polyethylene terephthalate used as the polymer support is preferably from 2 equivalent/t to 35 equivalent/t, more preferably from 5 equivalent/t to 25 equivalent/t, and particularly preferably from 7 equivalent/t to 25 equivalent/t. By setting the carboxyl group content to from 2 equivalent/t to 35 equivalent/t, it is possible to retain the hydrolysis resistance and restrain the strength degradation to a minimum with wet heat over time.

Furthermore, “equivalent/t” is a unit that expresses the molar equivalent per 1 t.

When polyester used in the polymer support is polymerized, a Sb compound, a Ge compound, and/or a Ti compound are preferably used as a catalyser, from the viewpoint of suppressing the carboxyl group content to the predetermined range or less, and among these, a Ti compound compound is particularly preferable. In a synthesis of polyester by using a Ti compound compound, for example, methods described in Japanese Examined Patent Application Publication No. H08-301198, Japanese Patent No. 2543624, Japanese Patent No. 3335683, Japanese Patent No. 3717380, Japanese Patent No. 3897756, Japanese Patent No. 3962226, Japanese Patent No. 3979866, Japanese Patent No. 3996871, Japanese Patent No. 4000867, Japanese Patent No. 4053837, Japanese Patent No. 4127119, Japanese Patent No. 4134710, Japanese Patent No. 4159154, Japanese Patent No. 4269704, Japanese Patent No. 4313538, or the like can be applied.

The polymer support more preferably includes a polymer polymerized in the presence of a titanium catalyst.

The solid phase polymerization of polyester that configures the polymer support is preferably performed after polymerization. According to this, it is possible to accomplish the preferable carboxyl group content. The solid phase polymerization is a technique which increases the degree of polymerization by heating polyester which is pre-polymer after polymerization for approximately 5 hours to 100 hours at a temperature from approximately 170° C. to 240° C. in vacuo or in nitrogen gas. Specifically, in the solid phase polymerization, methods described in Japanese Patent No. 2621563, Japanese Patent No. 3121876, Japanese Patent No. 3136774, Japanese Patent No. 3603585, Japanese Patent No. 3616522, Japanese Patent No. 3617340, Japanese Patent No. 3680523, Japanese Patent No. 3717392, Japanese Patent No. 4167159, or the like can be applied.

Polyester used in the polymer support is preferably biaxially stretched from the point of mechanical strength.

The polymer support is preferably treated by heat at a temperature from 180° C. to 220° C. after stretching, more preferably treated by heat at a temperature from 190° C. to 215° C., and particularly preferably treated by heat at a temperature from 195° C. to 215° C. Setting the heat treatment temperature to 180° C. or more is preferable from the viewpoint of improving size change of the polymer support by relaxing the deformation of the polymer support after stretching, and setting to 220° C. or less is preferable from the viewpoint of improving the hydrolysis resistance and size change of the polymer support at the same time by regulating not to excessively progress the orientation of the polymer when the deformation of the polymer support after stretching is relaxed.

The solid phase polymerization of a polymer that configures the polymer support is preferably performed. As the solid phase polymerization described above, for example, a polymerization method in which a polymer which is a pre-polymer is put in a vacuum resistant vessel, the inside of the vessel is evacuated, and the reaction is performed while stirring is included.

˜Thickness˜

The thickness of the polymer support is 220 μm or more and is preferably from 220 μm to 250 μm.

The surface of the polymer support may be treated by a method such as corona treatment, flame treatment or glow discharge treatment as necessary, or may not be treated. In one embodiment, it is possible to treat the surface of the polymer support by a method selected from a group that consists of corona treatment, flame treatment and glow discharge treatment and dispose the second polymer layer and the first polymer layer, in this order, on the surface of the treated polymer support.

Corona discharge treatment usually ionizes air between electrodes to generate corona discharge between electrodes occur by applying high frequency and high voltage to a metal roll coated by a dielectric (a dielectric roll) and between insulated electrodes to make an air insulation breakdown between electrodes occur. Then, corona discharge treatment is performed by passing the support between this corona discharge.

In one embodiment, the conditions of corona discharge treatment are preferably a gap clearance between electrodes and a dielectric roll of from 1 mm to 3 mm, the frequency of from 1 kHz to 100 kHz and applied energy of from approximately 0.2 kV·A·min/m² to 5 kV·A·min/m².

Glow discharge treatment is a method which is called vacuum plasma treatment or glow discharge treatment and a method of treating the base surface by generating the plasma by discharging in a gas of the low pressure atmosphere (a plasma gas). The low pressure plasma used here is the nonequilibrium plasma which is generated under the condition in which the pressure of the plasma gas is low. Glow discharge treatment can be conducted by placing a film to be treated in this low pressure plasma atmosphere.

Examples of a method for generating the plasma in grow discharge treatment include a direct-current glow discharge, a high frequency discharge, and a microwave discharge. A power source used for discharging may be a direct current or an alternating current. In a case where an alternating current is used, it is preferably in a range of from approximately 30 Hz to 20 Mhz. In a case where an alternating current is used, the commercial frequency of either 50 Hz or 60 Hz may be used, or the high frequency which is from approximately 10 kHz to 50 kHz may be used. A method of using the high frequency of 13.56 MHz is also preferable.

As a plasma gas used in glow discharge treatment, inorganic gas such as oxygen gas, nitrogen gas, water vapour gas, argon gas, helium gas is included and oxygen gas or the mixed gas of oxygen gas and argon gas is preferable. In one embodiment, the mixed gas of oxygen gas and argon gas is desirably used. In a case of using oxygen gas and argon gas, the ratio of both is approximately oxygen gas:argon gas=100:0 to 30:70, and more preferably approximately 90:10 to 70:30, as a division ratio. A method which does not particularly introduce a gas into a treatment vessel but uses, as the plasma gas, a gas such as an air which enters a treatment vessel due to leaking or water vapour released from the object to be treated is also preferable.

A low pressure which can accomplish the nonequilibrium plasma condition is needed as a pressure of the plasma gas. The specific pressure of the plasma gas is from 0.005 Torr to 10 Torr, and more preferably in a range of from approximately 0.008 Torr to 3 Torr. When the pressure of the plasma gas is 0.005 Torr or more, a sufficient effect of an improvement of adhesive properties may be expected, and when it is 10 Torr or less, destabilization of the discharge due to an increase of current may be prevented.

While it all depends on a shape and a size of a treatment vessel, a shape of an electrode, or the like, a plasma output is preferably from approximately 100 W to 2,500 W, and more preferably from approximately 500 W to 1,500 W.

In one embodiment, a treatment time of glow discharge treatment is preferably from 0.05 sec to 100 sec, and more preferably from approximately 0.5 sec to 30 sec. When the treatment time is 0.05 or more, a sufficient effect of an improvement of adhesive properties may be expected, and when being 100 sec or less, deformation, coloration, or the like of a film to be treated may be prevented.

A strength of the discharge treatment of glow discharge treatment is preferably in a range of from 0.01 kV·A·min/m² to 10 kV·A·min/m², and more preferably 0.1 kV·A·min/m² to 7 kV·A·min/m², depending on the plasma output and the treatment time. By setting the strength of the discharge treatment to 0.01 kV·A·min/m² or more, a sufficient effect of an improvement of adhesive properties may be obtained, and by setting to 10 kV·A·min/m² or less, deformation, coloration, or the like of a film to be treated may be avoided.

In glow discharge treatment, it is also preferable that a film to be treated be heated in advance. According to this method, excellent adhesive properties in a short time may be obtained, compared with a case in which heating is not conducted. The temperature of heating is preferably in a range of from 40° C. to a softening temperature of a film to be treated plus 20° C., and more preferably in a range of from 70° C. to a softening temperature of a film to be treated. By setting the heating temperature to 40° C. or more, a sufficient effect of an improvement of adhesive properties may be obtained. In addition, by setting the heating temperature to the softening temperature of a film to be treated or less, excellent handling property of a film during the treatment may be ensured.

Examples of a specific method of increasing the temperature of a film to be treated in vacuo include heating the film by using an infrared heater and heating by bringing the film into contact with a heated roll.

The polymer support may contain or may not contain a terminal sealing agent. The polymer support that contains a terminal sealing agent can have an improved hydrolysis resistance (weather resistance).

The polymer support may contain or may not contain inorganic particles or organic particles. The polymer support that contains inorganic particles or organic particles can have an improved light reflectance (a degree of whiteness).

(Terminal Sealing Agent)

In one embodiment, the polymer support may include or may not include from 0.1% by mass to 10% by mass of a terminal sealing agent with respect to a total mass of the polymer which configures the polymer support. In one embodiment, a content of the terminal sealing agent can be preferably from 0.2% by mass to 5% by mass, and more preferably from 0.3% by mass to 2% by mass.

Hydrolysis of the polymer is accelerated by a catalytic effect of a hydrogen ion generated from the terminal carboxyl group or the like. Therefore, it can be effective to add the terminal sealing agent which reacts with the terminal carboxyl group in order to improve a hydrolysis resistance (weather resistance). When the content of the terminal sealing agent is within the range described above, a decrease in the mechanical strength and heat-resisting properties of the polymer support may be avoided since the terminal sealing agent acts as a plasticizer with respect to the polymer.

Examples of the terminal sealing agent include an epoxy compound, a carbodiimide compound, an oxazoline compound, and a carbonate compound. Carbodiimide which has high affinity with PET and high terminal sealing ability is preferable.

When the terminal sealing agent (particularly, a carbodiimide terminal sealing agent) has a high molecular weight, vaporization during melt film casting may be reduced. The molecular weight is preferably from 200 to 100,000, more preferably from 2,000 to 80,000, and even more preferably from 10,000 to 50,000, as the weight average molecular weight. When the weight average molecular weight of the terminal sealing agent (particularly, a carbodiimide terminal sealing agent) is 50,000 or less, it easily uniformity disperse in a polymer, and an effect of an improvement of the weather resistance may be sufficiently exerted. When the weight average molecular weight described above is 10,000 or more, it is possible to suppress vaporization during extrusion and/or film forming and to exert an effect of an improvement of the weather resistance.

Carbodiimide Terminal Sealing Agent

A carbodiimide terminal sealing agent is a carbodiimide compound which has a carbodiimide group. In the carbodiimide compound, there are a monofunctional carbodiimide and a multifunctional carbodiimide Examples of the monofunctional carbodiimide include dicyclohexyl carbodiimide, diisopropyl carbodiimide, dimethyl carbodiimide, diisobutyl carbodiimide, dioctyl carbodiimide, t-butyl isopropyl carbodiimide, diphenyl carbodiimide, di-t-butyl-carbodiimide, and di-β-naphthyl carbodiimide. Dicyclohexylcarbodiimide and diisopropyl carbodiimide are preferable.

As a multifunctional carbodiimide, a carbodiimide that has the degree of polymerization of 3 to 15 is preferably used. Specific examples thereof include 1,5-naphthalene carbodiimide, 4,4′-diphenylmethane carbodiimide, 4,4′-diphenyl dimethyl methane carbodiimide, 1,3-phenylene carbodiimide, 1,4-phenylene carbodiimide, 2,4-tolylene carbodiimide, 2,6-tolylene carbodiimide, a mixture of 2,4-tolylene carbodiimide and 2,6-tolylene carbodiimide, hexamethylene carbodiimide, cyclohexane-1,4-carbodiimide, xylylene carbodiimide, isophorone carbodiimide, isophorone carbodiimide, dicyclohexyl methane-4,4′-carbodiimide, methyl cyclohexane carbodiimide, tetramethyl xylylene carbodiimide, 2,6-diisopropylphenylcarbodiimide, and 1,3,5-triisopropylbenzene-2,4-carbodiimide.

Since the carbodiimide compound generates an isocyanate gas by thermal decomposition, the terminal sealing agent is preferably a carbodiimide compound which has high heat-resisting properties. In order to enhance heat-resisting properties, the higher the molecular weight (the degree of polymerization) of the carbodiimide compound is more preferable, and it is preferable that the terminus of the carbodiimide compound have a structure that has high heat-resisting properties. Carbodiimide compounds tend to easily cause thermal decomposition once a thermal decomposition occur. Accordingly, in a manufacture of the polymer support, a devisal such as that makes the extrusion temperature of the polymer into a low-temperature as much as possible may be performed.

In one embodiment, the carbodiimide compound of the terminal sealing agent is preferably a compound which has a cyclic structure (for example, a compound described in JP-A No. 2011-153209). Although these are of low molecular weight, these may exert the same level effect as the high molecular weight carbodiimide described above. This is because generation of an isocyanate gas can be suppressed since the terminal carboxyl group and the cyclic carbodiimide of the polymer are subjected to a ring-opening reaction, and one is reacted with this terminal carboxyl group and the other which is ring-opened is reacted with other terminal carboxyl group to increase the molecular weight.

In one embodiment, the terminal sealing agent which is the carbodiimide compound that has a cyclic structure is preferably a terminal sealing agent which includes a cyclic structure in which a first nitrogen and a second nitrogen of a carbodiimide group are bonded with a binding group. In one embodiment, the terminal sealing agent is preferably carbodiimide which has at least one carbodiimide group adjacent to an aromatic ring, and which includes a cyclic structure in which a first nitrogen and a second nitrogen of the carbodiimide group adjacent to an aromatic ring are bonded with a binding group (referred to as an aromatic cyclic carbodiimide).

The aromatic cyclic carbodiimide may have plural cyclic structures.

An aromatic carbodiimide that does not include two or more ring structures in which a first nitrogen and a second nitrogen of carbodiimide groups in a molecule are bonded with a linking group, in other words, an aromatic cyclic carbodiimide which is monocyclic, can be also preferably used as the aromatic cyclic carbodiimide.

The cyclic structure has one carbodiimide group (—N═C═N—) and a first nitrogen and a second nitrogen thereof are bonded with a binding group. In one cyclic structure, only one carbodiimide group is included. However, for example, in a case of having plural cyclic structures in a molecule, such as a spiro ring, as long as one carbodiimide group is included in the each cyclic structure which bonds to a spiro atom, a plurality of carbodiimide groups may be included in a compound. A number of atoms in a cyclic structure is preferably from 8 to 50, more preferably from 10 to 30, even more preferably from 10 to 20, and particularly preferably from 10 to 15.

Here, the number of atoms in a cyclic structure means a number of atoms which directly configure the cyclic structure, and for example, when the cyclic structure is a eight-membered ring, the number of atoms is 8, and when the cyclic structure is a fifty-membered ring, the number of atoms is 50. When the number of atoms in the cyclic structure is 8 or more, the cyclic carbodiimide compound can maintain the stability and it can be suitable for storage and usage. An upper limit value of the number of member-ring is not particularly limited from the viewpoint of reactivity, while the cyclic carbodiimide compound is preferably 50 or less from the viewpoint of being able to suppress cost rise due to difficulty in synthesis. From these viewpoints, a range of the number of atoms in the cyclic structure can be preferably from 10 to 30, more preferably from 10 to 20, and even more preferably from 10 to 15.

Specific examples of the carbodiimide sealing agent which has a cyclic structure include the following compounds. However, the present invention is not limited to the following specific examples.

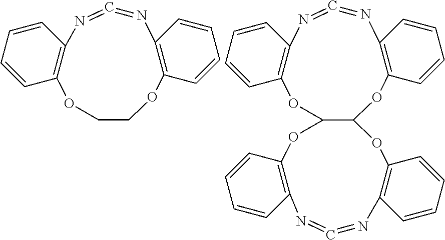

Epoxy Terminal Sealing Agent

An epoxy terminal sealing agent is an epoxy compound. As a preferable example of the epoxy compound, a glycidyl ester compound, a glycidyl ether compound, and the like are included.

As a specific example of the glycidyl ester compound, benzoic acid glycidyl ester, t-Bu-benzoic acid glycidyl ester, P-toluic acid glycidyl ester, cyclohexane carboxylic acid glycidyl ester, pelargonic acid glycidyl ester, stearic acid glycidyl ester, lauric acid glycidyl ester, palmitic acid glycidyl ester, behenic acid glycidyl ester, versatic acid glycidyl ester, oleic acid glycidyl ester, linoleic acid glycidyl ester, linolenic acid glycidyl ester, behenolic acid glycidyl ester, stearolic acid glycidyl ester, terephthalic acid diglycidyl ester, isophthalic acid diglycidyl ester, phthalic acid diglycidyl ester, naphthalene dicarboxylic acid diglycidyl ester, methylterephthalic acid diglycidyl ester, hexahydrophthalic acid diglycidyl ester, tetrahydrophthalic acid diglycidyl ester, cyclohexanedicarboxylic acid diglycidyl ester, adipic acid diglycidyl ester, succinic acid diglycidyl ester, sebacic acid diglycidyl esters, dodecanedioic acid diglycidyl ester, octadecanedicarboxylic acid diglycidyl ester, trimellitic acid triglycidyl ester, pyromellitic acid tetraglycidyl ester, and the like are included. These can be used as one kind or two or more kinds.

In addition, as a specific example of the glycidyl ether compound, phenyl glycidyl ether, O-phenyl glycidyl ether, 1,4-bis(β,γ-epoxy propoxy)butane, 1,6-bis(β,γ-epoxy propoxy)hexane, 1,4-bis(β,γ-epoxy propoxy)benzene, 1-βγ-epoxy propoxy)-2-ethoxy ethane, 1-βγ-epoxy propoxy)-2-benzyloxy ethane, 2,2-bis-[p-(β,γ-epoxy propoxy)phenyl]propane, 2,2-bis-(4-hydroxyphenyl)]propane, bisglycidyl polyether obtained by the reaction of bisphenol such as 2,2-bis-(4-hydroxyphenyl)methane and epichlorohydrin, and the like are included. These can be used as one kind or two or more kinds.

Oxazoline Terminal Sealing Agent

An oxazoline terminal sealing agent is an oxazoline compound. As an oxazoline compound, a bisoxazoline compound is preferable, and specifically, examples can include 2,2′-bis(2-oxazoline), 2,2′-bis(4-methyl-2-oxazoline), 2,2′-bis(4,4-dimethyl-2-oxazoline), 2,2′-bis(4-ethyl-2-oxazoline), 2,2′-bis(4,4′-diethyl-2-oxazoline), 2,2′-bis(4-propyl-2-oxazoline), 2,2′-bis(4-butyl-2-oxazoline), 2,2′-bis(4-hexyl-2-oxazoline), 2,2′-bis(4-phenyl-2-oxazoline), 2,2′-bis(4-cyclohexyl-2-oxazoline), 2,2′-bis(4-benzyl-2-oxazoline), 2,2′-p-phenylenebis(2-oxazoline), 2,2′-m-phenylenebis(2-oxazoline), 2,2′-o-phenylenebis(2-oxazoline), 2,2′-p-phenylenebis(4-methyl-2-oxazoline), 2,2′-p-phenylenebis(4,4-dimethyl-2-oxazoline), 2,2′-m-phenylenebis(4-methyl-2-oxazoline), 2,2′-m-phenylenebis(4,4-dimethyl-2-oxazoline), 2,2′-ethylenebis(2-oxazoline), 2,2′-tetramethylenebis(2-oxazoline), 2,2′-hexamethylenebis(2-oxazoline), 2,2′-octamethylenebis(2-oxazoline), 2,2′-decamethylenebis(2-oxazoline), 2,2′-ethylenebis(4-methyl-2-oxazoline), 2,2′-tetramethylenebis(4,4-dimethyl-2-oxazoline), 2,2′-9,9′-diphenoxyethanebis(2-oxazoline), 2,2′-cyclohexylenebis(2-oxazoline), 2,2′-diphenylenebis(2-oxazoline), and the like. Among these, 2,2′-bis(2-oxazoline) is most preferably used, from the viewpoint of the reactivity with polyester. Furthermore, as long as an object of the present invention is achieved, the bisoxazoline compounds described above may be used as one kind alone or may be used as a combination of two or more kinds.

Such a terminal sealing agent is introduced by a method of kneading into a polymer which configures the polymer support, or the like. By the terminal sealing agent directly being brought into contact with a polymer molecule to react, the effect described above can be obtained. Even the terminal sealing agent is added onto a coating layer on PET, the polymer and the terminal sealing agent are not reacted.

(Polymer Support Mixed Inorganic Particles or Organic Particles)

The polymer which configures the polymer support may contain fine particles which are inorganic particles or organic particles. Thereby, it is possible to improve the light reflectance (the degree of whiteness) and improve power generation efficiency of the solar cell. The average particle diameter of fine particles can be preferably from 0.1 μm to 10 μm, more preferably from 0.1 μm to 5 μm, and even more preferably from 0.15 μm to 1 μm, and the content can be from 0% by mass to 50% by mass, preferably from 1% by mass to 10% by mass, and more preferably from 2% by mass to 5% by mass, with respect to a total mass of the polymer. When the average particle diameter of particles is from 0.1 μm to 10 μm, it is easy to make the degree of whiteness of the polymer support be 50 or more. When the content of particles is 1% by mass or more, it is easy to make the degree of whiteness be 50 or more. When the content of particles is 50% by mass or less, since the weight of the polymer support does not become too large, it is easy to handle in processing, or the like. Further, the term of the average particle diameter and the content here indicates the weighted average value based on the average values of each layer in a case where the polymer support has a multilayer structure. That is, the average particle diameter indicates a value in which (the average value of the particle diameter of each layer)×(the thickness of each layer/the thickness of all layers) is calculated by each layer to sum up, and the content indicates a value in which (the average value of the particle content of each layer)×(the thickness of each layer/the thickness of all layers) is calculated by each layer to sum up.

The average particle diameter of fine particles is determined by an electron microscopy. Specifically, the following method is applied.

Fine particles are observed with a scanning electron microscope, the magnification is arbitrarily changed according to the size of particles, and a picture which is taken is enlarged with a copier. Next, as to at least 200 or more of fine particles selected at random, outer peripheries of each particle are traced. The equivalent circle diameter of particles from these traced images is measured with an image analysis equipment. The average of the measured value is set to the average particle diameter.

Fine particles may be any one of inorganic particles or organic particles and both may be used together. The light reflectance may be improved thereby so that power generation efficiency of the solar cell may be improved. As inorganic particles which are suitably used, for example, wet and dry silica, colloidal silica, calcium carbonate, aluminum silicate, calcium phosphate, alumina, magnesium carbonate, zinc carbonate, titanium oxide, zinc oxide (zinc flower), antimony oxide, cerium oxide, zirconium oxide, tin oxide, lanthanum oxide, magnesium oxide, barium carbonate, zinc carbonate, lead carbonate basic (white lead), barium sulfate, calcium sulfate, lead sulfate, zinc sulfide, mica, mica titanium, talc, clay, kaolin, lithium fluoride, calcium fluoride, and the like can be included, however, titanium dioxide and barium sulfate are particularly preferable. Furthermore, titanium oxide may be any of anatase-type or rutile-type. In addition, inorganic surface treatment may be performed by using alumina, silica, or the like, or organic surface treatment may be performed by using a silicon compound, alcohol, or the like, on the surface of fine particles.

Among these fine particles, titanium dioxide is preferable and by the polymer support containing this, the polymer sheet can achieve excellent durability even under the photo irradiation. Specifically, in a case of irradiating with ultraviolet rays for 100 hours, at 63° C., at 50% Rh, and the radiation intensity of 100 mW/cm², the retention rate of the elongation at break can be preferably 35% or more, and more preferably 40% or more. Since the photodecomposition or the degradation can be suppressed, the polymer sheet in this embodiment is more suitable as a film for protecting a back surface of the solar cell used outdoors.

In titanium dioxide, titanium dioxide which has a rutile-type crystal structure and titanium dioxide which has a anatase-type crystal structure are present. In one embodiment, it is preferable that fine particles mainly composed of rutile-type titanium dioxide be added into the polymer support. The spectral reflectance of ultraviolet rays is very large in the anatase-type, whereas the rutile-type has characteristics in which the ratio of absorption of ultraviolet rays is large (the spectral reflectance is small). The present inventors found that it is possible to improve the light resistance in the polymer sheet for protecting the back surface of the solar cell, by focusing on the difference of these spectral characteristics in a crystal form titanium dioxide and using the absorption performance of ultraviolet rays of rutile-type titanium dioxide. In the present embodiment, excellent film durability may be obtained under the photo irradiation without substantively adding other ultraviolet absorbing agent. Therefore, problems such as contamination due to bleed-out of an ultraviolet absorbing agent and a decrease in adhesion hardly occur.

The term fine particles are “mainly composed of rutile-type titanium dioxide” here means that the mass of rutile-type titanium dioxide in all titanium dioxide particles is over 50% by mass, with respect to the mass of all titanium dioxide particles. In addition, the amount of anatase-type titanium dioxide in all titanium dioxide particles is preferably 10% by mass or less, more preferably 5% by mass or less, and particularly preferably 0% by mass or less, with respect to the mass of all titanium dioxide particles. When the content of anatase-type titanium dioxide is the upper limit value or less, since the amount of rutile-type titanium dioxide occupied in all titanium dioxide particles may be ensure, the absorption performance of ultraviolet rays can be ensured. Since anatase-type titanium dioxide has strong photocatalytic action, the light resistance of the polymer sheet also tends to decrease due to this action. It is possible to distinguish between rutile-type titanium dioxide and anatase-type titanium dioxide by an X-ray structural analysis or the optical absorption characteristics.

Inorganic surface treatment may be performed by using alumina, silica, or the like, or organic surface treatment may be performed by using a silicon compound, alcohol, or the like, on the surface of fine particles of rutile-type titanium dioxide. Before rutil-type titanium dioxide is combined into a polyester composition, regulate of the particle diameter, removal of the coarse particles, or the like may be performed by using the refining process. As an industrial means of the refining process, for example, pulverization means such as jet mill and ball mill and classification means such as wet or dry centrifugal separation, or the like are included.

Organic fine particles that can be contained in the polymer support are preferably organic fine particles which can stand the heat during the film forming For example, fine particles composed of a cross-linked type resin, specifically, fine particles composed of polystyrene which is cross-linked by divinylbenzene, or the like are included. The size and the addition amount of fine particles are the same size and the addition amount as inorganic fine particles.

As a method in which fine particles are added into the polymer support, various kinds of conventionally known methods can be used. The representative methods thereof are given as follows.

(1) A method of adding fine particles at transesterification or before esterification is completed during the synthesis of the polymer that configures the polymer support, or adding fine particles before the initiation of polycondensation reaction.

(2) A method of adding fine particles into the polymer, and performing melting and kneading.

(3) A method of manufacturing a master-pellet (also referred to as a master batch (MB)) to which the large amount of fine particles is added, kneading these and the polymer that does not contain fine particles, and making the predetermined amount of fine particles contain in the obtained product in the methods of (1) and (2).

(4) A method of using the master-pellet in the (3) without any change.

In one embodiment, a master batch method (a MB method: the (3)) that includes mixing a polyester resin and fine particles by an extruding machine in advance is preferable. In addition, a method in which the polymer which is not dried and fine particles are put into an extruding machine in advance and the MB is produced while deaerating moisture, air or the like can be also employed. Further, it is possible to suppress the increase of the acid value of the polymer by preferably producing the MB using the polymer that has been dried even a little in advance. As such method, a method of extruding while deaerating, a method of extruding without deaerating due to the polymer which is sufficiently dried, and the like are included.

For example, in a case of producing the MB, it is preferable that the moisture percentage of the polymer which is put into by drying in advance be reduced. As the drying conditions, drying is performed for 1 hour or more, more preferably for 3 hours or more, and even more preferably for 6 hours or more, preferably at 100° C. to 200° C., and more preferably at 120° C. to 180° C. In this manner, a polyester resin is sufficiently dried so that the amount of moisture of a polyester resin is preferably 50 ppm or less, and more preferably 30 ppm or less. A method of premixing is not particularly limited, and may be a method by a batch or by a single or twin screws or more kneading extruders. In a case of producing the MB while deaerating, a method in which the polymer is melted at a temperature of from 250° C. to 300° C., and preferably at 270° C. to 280° C., a pre-kneader is provided with one deaeration hole, and preferably two or more deaeration holes, and a continuous suction deaeration is performed at 0.05 MPa or more, and more preferably at 0.1 MPa or more to maintain the reduction of pressure in the mixer, or the like is preferably employed.

In one embodiment, the polymer support may internally contain a large number of fine cavities (voids). In this manner, it is possible to suitably obtain higher degree of whiteness. In the case, apparent specific gravity is from 0.7 to 1.3, preferably from 0.9 to 1.3, and more preferably 1.05 to 1.2. When apparent specific gravity is 0.7 or more, the polymer sheet may have stiffness, and processing of the polymer sheet can be facilitated during the production of the solar cell module. The apparent specific gravity of 1.3 or less may contribute to reducing the weight of the solar cell, since the weight of the polymer sheet is small

The fine cavities can be formed as that derived from a thermoplastics resin which is incompatible with fine particles described above and/or the polymer that configures the polymer support described below. The “cavities derived from a thermoplastics resin which is incompatible with fine particles or the polymer” indicates that the cavities around fine particles described above or the thermoplastics resin described above are present, and the cavities can be observed by, for example, a cross section picture of the polymer support by an electron microscope.

A resin which can be added into the polymer support in order to form the cavities is preferably a resin which is incompatible with the polymer that configures the polymer support. It is possible to scatter light and increase the light reflectance thereby. In a case where the polymer that configures the polymer support is polyester, examples of preferable incompatible resin include a polyolefin resin such as polyethylene, polypropylene, polybutene, polymethylpentene, a polystyrene resin, a polyacrylate resin, a polycarbonate resin, a polyacrylonitrile resin, a polyphenylene sulfide resin, a polysulfone resin, a cellulose resin, and a fluorine resin. These incompatible resins may be a homopolymer or may be a copolymer, and may be used as a combination of two or more kinds of incompatible resins. Among these, a polyolefin resin such as polypropylene and polymethylpentene or a polystyrene resin, which have small surface tension, is preferable, and polymethylpentene is more preferable. Since the difference in surface tension between polymethylpentene and polyester is relatively large and the melting point of polymethylpentene is high, the affinity of polymethylpentene to polyester is low and the voids (the cavities) are easily formed in the process of the polyester film formation.

In a case where the polymer support contains an incompatible resin, the amount thereof is in a range of from 0% by weight to 30% by weight, more preferably from 1% by weight to 20% by weight, and even more preferably from 2% by weight to 15% by weight, with respect to the entire polymer support. When the content is 30% by weight or less, since apparent density of the entire polymer support can be ensured, breaking a film or the like may hardly occur when stretching and excellent productivity may be obtained.

In a case of adding fine particles, the average particle diameter of fine particles is preferably from 0.1 μm to 10 μm, more preferably from 0.1 μm to 5 μm, and even more preferably from 0.15 μm to 1 μm. When the average particle diameter is 0.1 μm or more, the reflectance (degree of whiteness) may be ensured, and when the average particle diameter is 10 μm or less, a decrease in mechanical strength due to the voids may be avoided. The content of fine particles is from 0% by mass to 50% by mass, preferably from 1% by mass to 10% by mass, and more preferably 2% by mass to 5% by mass, with respect to the total mass of the polymer support. When the content is 50% by mass or less, a decrease in mechanical strength due to the voids may be avoided. In a case where the polymer that configures the polymer support is polyester, preferable examples of the fine particles include fine particles having a low affinity for polyester, and specifically, barium sulphate and the like are included.

A white polymer support, that is, the polymer support that contains the cavities formed by means of containing fine particles, or the like, may be a single layer or a layered configuration that consists of multilayer of two or more layers. As a layered configuration, it is preferable that a layer that has the high degree of whiteness (a layer that has many voids and fine particles) and a layer that has the low degree of whiteness (a layer that has less voids and fine particles) be combined. Although the layer that has many voids and fine particles can make the light reflection efficiency higher, a decrease in mechanical strength (embrittlement) due to the voids and fine particles easily occurs, and in order to compensate for this, it is preferable to combine with the layer that has the low degree of whiteness. Therefore, the layer that has the high degree of whiteness is preferably used on the outer layer of the polymer support, and may be used on one side on the polymer support or may be used on both sides of the polymer support. When a layer having high degree of whiteness in which titanium dioxide is used as fine particles is used on the outer layer of the polymer support, it is possible to obtain an effect which improves the light resistance of the polymer support due to titanium dioxide having ultraviolet ray-absorbing property.

In a case where the layer that has the high degree of whiteness is a layer formed by containing fine particles, the content of fine particles to the mass of the entire layers is preferably from 5% by mass to 50% by mass, and more preferably from 6% by mass to 20% by mass. In a case where the layer that has the high degree of whiteness is a layer formed by forming the cavities, apparent specific gravity of the layer that has the high degree of whiteness is preferably from 0.7 to 1.2, and more preferably from 0.8 to 1.1. On the other hand, in a case where the layer that has the low degree of whiteness is a layer formed by containing fine particles, the content of fine particles to the mass of the entire layers is preferably 0% by mass or more and less than 5% by mass, and more preferably from 1% by mass to 4% by mass. In a case where the layer that has the high degree of whiteness is a layer formed by forming the cavities, it is preferable that apparent specific gravity of the layer that has low degree of whiteness be preferably from 0.9 to 1.4 and the layer that has the low degree of whiteness have higher apparent specific gravity than the layer having high degree of whiteness, and it is more preferable that apparent specific gravity be from 1.0 to 1.3 and the layer that has the low degree of whiteness have higher apparent specific gravity than the layer having high degree of whiteness. It dose not matter if the layer having low degree of whiteness does not include fine particles or the cavities.

As a preferable layered configuration in which the white polymer support can contain, layer having high degree of whiteness/layer having low degree of whiteness, layer having high degree of whiteness/layer having low degree of whiteness/layer having high degree of whiteness, layer having high degree of whiteness/layer having low degree of whiteness/layer having high degree of whiteness/layer having low degree of whiteness, layer having high degree of whiteness/layer having low degree of whiteness/layer having high degree of whiteness/layer having low degree of whiteness/layer having high degree of whiteness, and the like are included.

The thickness ratio of each layer in the layered configuration is not particularly limited, while the thickness of each layer is preferably from 1% to 99%, and more preferably from 2% to 95%, of the thickness of all layers. When being within this range, it is easy to obtain an effect of improving of the reflection efficiency described above and imparting the light resistance (UV). The thickness of all layers of the polymer support is not particularly limited as long as the thickness is in the range capable of forming a film as a film, however, usually in a range of from 20 μm to 500 μm, and preferably 25 μm to 300 μm. As a method of layering for manufacturing the polymer support that has the layered configuration, using two machines or three or more machines of a melting extruder, a so-called coextrusion method is preferably used.

In one embodiment, a fluorescent brightening agent such as thiophenediyl is also preferably used in order to increase the degree of whiteness of the white polymer support. The addition amount is preferably from 0.01% by mass to 1% by mass, more preferably from 0.05% by mass to 0.5% by mass, and even more preferably from 0.1% by mass to 0.3% by mass, with respect to the total mass of the white polymer support. When the addition amount is 0.01% by mass or more, it is easy to obtain an effect of improving light beam reflectance, and when the addition amount is 1% by mass or less, it is possible to avoid a decrease in the reflectance due to yellowing by the thermal decomposition during extruding. As such fluorescent brightening agent, for example, OB-1 (trade name) manufactured by Eastman Kodak Co., or the like can be used.

In one embodiment, it is preferable that the amount of change in yellowish (Δb value) be less than 5 after the white polymer support is irradiated with ultraviolet rays under the conditions of illumination: 100 mW/cm², temperature: 60° C., relative humidity: 50% RH and irradiation time: 48 hours. Δb value is more preferably less than 4, and even more preferably less than 3. In this manner, even sunlight irradiation is received for long period of time, it is useful from the point of decreasing in chromatic change. Such an effect prominently appears particularly when irradiation is received from the side of the polymer sheet in a solar cell module in which the polymer sheet as a backsheet are layered on the solar cell.

(First Polymer Layer)

A polymer sheet in the first embodiment of the present invention includes a first polymer layer that contains at least one selected from a group that consists of a fluorine polymer and a silicone polymer.

The first polymer layer is a layer which can function as a weather resistance layer.

˜Binder˜

The first polymer layer is configured by at least one selected from a group that consists of the fluorine polymer and the silicone polymer as a main binder. Here, the main binder in the first polymer layer means a binder in which the content is the largest among the binders included in the first polymer layer.

In the first polymer layer, the polymer selected from a group that consists of the fluorine polymer and the silicone polymer may be used as only one kind or the polymer selected from a group that consists of the fluorine polymer and the silicone polymer may be used as a combination of two or more kinds. In a case where the fluorine polymer and the silicone polymer are used together, two or more kinds of polymers from any one of the fluorine polymer and the silicone polymer may be selected to use together or one kind or two or more kinds from both of the fluorine polymer and the silicone polymer may be selected to use together.

Hereinafter, specific description will be given of the first polymer layer that contains at least one kind of polymer selected from the fluorine polymer and the silicone polymer described above.

—Fluorine Polymer—

A fluorine polymer in which the first polymer layer can contain is not particularly limited as long as the fluorine polymer is a polymer that has a repeated unit represented by —(CFX¹—CX²X³)— (However, X¹, X² and X³ represent a hydrogen atom, a fluorine atom, a chlorine atom or a perfluoroalkyl group that has from 1 to 3 carbon atoms).

Examples of the fluorine polymer include polytetrafluoroethylene (hereinafter, there are cases where being represented as PTFE), polyvinyl fluoride (hereinafter, there are cases where being represented as PVF), polyvinylidene fluoride (hereinafter, there are cases where being represented as PVDF), polychloro trifluoroethylene (hereinafter, there are cases where being represented as PCTFE), and hexafluoropropylene (hereinafter, there are cases where being represented as HFP).

The fluorine polymer may be a homopolymer in which a solo monomer is polymerized or may be a polymer in which two or more kinds are copolymerized. As this example, a copolymer in which tetrafluoroethylene is copolymerized with hexafluoropropylene (abbreviated as P(TFE/HFP)), a copolymer in which tetrafluoroethylene is copolymerized with vinylidene fluoride (abbreviated as P(TFE/VDF)), and the like can be included.

In addition, a polymer used in the first polymer layer may be also a polymer in which a fluorocarbon monomer represented by —(CFX¹—CX²X³)— is copolymerized with a monomer (a non-fluorine-containing monomer) except this. As a specific example of the fluorocarbon monomer, tetrafluoroethylene, chlorotrifluoroethylene, vinylidene fluoride, vinyl fluoride, hexafluoropropylene, fluorine-containing alkyl vinyl ether (example: perfluoroethyl vinyl ether), fluorine-containing ester, or the like (perfluorobutyl methacrylate, or the like) are included. As a specific example of the non-fluorine-containing monomer, ethylene, alkyl vinyl ether (example: ethyl vinyl ether and cyclohexyl vinyl ether), and carboxylic acid (example: acrylic acid, methacrylic acid, hydroxybutyl vinyl ether, or the like) are included. In a case where the fluorine polymer is a polymer in which the fluorocarbon monomer is copolymerized with the non-fluorine-containing monomer, the content of the fluorine-containing monomer to the total mass of the fluorine polymer is preferably from 30% by mass to 98% by mass, and more preferably from 40% by mass to 80% by mass. When the ratio of the fluorine-containing monomer is 30% by mass or more, it is possible to obtain sufficient durability. In addition, 98% by mass or less is preferable, from the viewpoint of the stability of the polymerization.

As an example of the polymer in which the fluorocarbon monomer is copolymerized with the non-fluorine-containing monomer, a copolymer formed by the copolymerization of tetrafluoroethylene with ethylene (abbreviated as P(TFE/E)), a copolymer formed by the copolymerization of tetrafluoroethylene with propylene (abbreviated as P(TFE/P)), a copolymer formed by the copolymerization of tetrafluoroethylene with vinyl ether (abbreviated as P(TFE/VE)), a copolymer formed by the copolymerization of tetrafluoroethylene with perfluorovinylether (abbreviated as P(TFE/FVE)), a copolymer formed by the copolymerization of chlorotrifluoroethylene with vinyl ether (abbreviated as P(CTFE/FVE)), a copolymer formed by the copolymerization of chlorotrifluoroethylene with perfluorovinylether (abbreviated as P(CTFE/FVE)), a copolymer formed by the copolymerization of tetrafluoroethylene with ethylene and acrylic acid, a copolymer formed by the copolymerization of hexafluoropropylene with tetrafluoroethylene, a copolymer formed by the copolymerization of hexafluoropropylene with tetrafluoroethylene and ethylene, a copolymer formed by the copolymerization of chlorotrifluoroethylene with perfluoro ethyl vinyl ether, a copolymer formed by the copolymerization of chlorotrifluoroethylene with perfluoro ethyl vinyl ether and methacrylic acid, a copolymer formed by the copolymerization of chlorotrifluoroethylene with ethyl vinyl ether, a copolymer formed by the copolymerization of chlorotrifluoroethylene with ethyl vinyl ether and methacrylic acid, a copolymer formed by the copolymerization of vinylidene fluoride with methyl methacrylate and methacrylic acid, a copolymer formed by the copolymerization of vinyl fluoride with ethyl acrylate and acrylic acid, and the like can be included.

Among these, a copolymer formed by the polymerization of chlorotrifluoroethylene with perfluoro ethyl vinyl ether, a copolymer formed by the copolymerization of chlorotrifluoroethylene with perfluoro ethyl vinyl ether and methacrylic acid, a copolymer formed by the copolymerization of chlorotrifluoroethylene with ethyl vinyl ether, a copolymer formed by the copolymerization of chlorotrifluoroethylene with ethyl vinyl ether and methacrylic acid, a copolymer formed by the copolymerization of vinylidene fluoride with methyl methacrylate and methacrylic acid and a copolymer formed by the copolymerization of vinyl fluoride with ethyl acrylate and acrylic acid are preferable.

Above all, a copolymer formed by the copolymerization of chlorotrifluoroethylene with ethyl vinyl ether and a copolymer formed by the copolymerization of chlorotrifluoroethylene with ethyl vinyl ether and methacrylic acid are more preferable.

As the fluorine polymer described above, the fluorine polymers which are commercially available can be used. Specific examples of the commercial products include LUMIFLON (registered trademark) LF200 (manufactured by ASAHI GLASS CO., LTD.), ZEFFLE (registered trademark) GK570 (manufactured by DAIKIN INDUSTRIES, LTD.), and OBBLIGATO SW0011F (trade name, manufactured by AGC COAT-TECK CO., LTD.).

The molecular weight of the fluorine polymer may be from approximately 2,000 to 1,000,000 and is preferably approximately from 3,000 to 300,000, as the weight average molecular weight in terms of polystyrene.

The fluorine polymer may be a polymer that can be used by dissolving a polymer in an organic solvent or a polymer that can be used by dispersing polymer fine particles in water. The latter is preferable from the point of the small environmental burden. Water dispersion of the fluorine polymer, for example, is described in JP-A No. 2003-231722, JP-A No. 2002-20409, JP-A No. H09-194538, or the like.

˜Silicone Polymer˜

A silicone polymer that can be contained in the first polymer layer is a polymer that has a (poly)siloxane structure in a molecule. Here, a “siloxane structure” means a structure that includes at least one siloxane bond. A “polysiloxane structure” means a structure continuously composed of plural siloxane bonds. The term “(poly)siloxane structure” includes a siloxane structure and a polysiloxane structure in the range. The expression of “a polymer has a siloxane structure in a molecule” and “a polymer has a (poly)siloxane structure in a molecule thereof” means that a polymer includes a siloxane structure or (poly)siloxane structure in the molecule.

In one preferable aspect, a silicone polymer has a (poly)siloxane structure unit represented by the following Formula (1), as a (poly)siloxane structure.

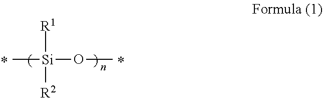

In Formula (1) described above, R¹ and R² each independently represent a hydrogen atom, a halogen atom, or a monovalent organic group. Here, R¹ and R² may be the same or different, and plural R¹'s and R²'s may be respectively the same as or different from each other. n represents an integer of 1 or more.

In a part of “—(Si(R¹)(R²)—O)ₙ—” which is a (poly)siloxane segment in a polymer ((poly)siloxane structure unit represented by Formula (1)), R¹ and R² may be the same or different, and represent a hydrogen atom, a halogen atom or a monovalent organic group.

“—(Si(R¹)(R²)—O)ₙ—” is a (poly)siloxane segment derived from various kinds of (poly)siloxanes that has a linear, branched or cyclic structure.

As a halogen atom represented by R¹ and R², a fluorine atom, a chlorine atom, an iodine atom, or the like can be included.

A “monovalent organic group” represented by R¹ and R² is a group capable of forming a covalent bond with a Si atom, and may be unsubstituted or may have a substituent. The monovalent organic group described above, for example, includes an alkyl group (example: a methyl group, an ethyl group, or the like), an aryl group (example: a phenyl group, or the like), an aralkyl group (example: a benzyl group, a phenylethyl, or the like), an alkoxy group (example: a methoxy group, an ethoxy group, a propoxy group, or the like), an aryloxy group (example: a phenoxy group, or the like), a mercapto group, an amino group (example: an amino group, a dimethylamino group, or the like), an amide group, or the like.

Among these, R¹ and R² each independently are preferably a hydrogen atom, a chlorine atom, a bromine atom, an unsubstituted or substituted alkyl group that has 1 to 4 carbon atoms (preferably a methyl group and an ethyl group), an unsubstituted or substituted phenyl group, an unsubstituted or substituted alkoxy group, a mercapto group, an unsubstituted amino group and an amide group, from the point of adhesive properties with a layer contacting thereto and the durability under a wet heat environment, and more preferably an unsubstituted or substituted alkoxy group (preferably an alkoxy group that has 1 to 4 carbon atoms), from the point of the durability under a wet-heat environment.

n described above is preferably from 1 to 5,000, and more preferably from 1 to 1,000.

As a specific example of the part of “—(Si(R¹)(R²)—O)ₙ—” in a silicone polymer (a (poly)siloxane structure unit represented by Formula (1)), a hydrolysis condensate that contains a hydrolysis condensate of dimethyldimethoxysilane, a hydrolysis condensate that contains a hydrolysis condensate of dimethyldimethoxysilane/γ-methacryloxytrimethoxysilane, a hydrolysis condensate that contains a hydrolysis condensate of dimethyldimethoxysilane/vinyltrimethoxysilane, a hydrolysis condensate that contains a hydrolysis condensate of dimethyldimethoxysilane/2-hydroxyethyltrimethoxysilane, a hydrolysis condensate that contains a hydrolysis condensate of dimethyldimethoxysilane/3-glycidoxypropyltrimethoxysilane, a hydrolysis condensate that contains a hydrolysis condensate of dimethyldimethoxysilane/diphenyl/dimethoxysilane γ-methacryloxytrimethoxysilane, and the like are included. Among these, a hydrolysis condensate that contains a hydrolysis condensate of dimethyldimethoxysilane/γ-methacryloxytrimethoxysilane, a hydrolysis condensate that contains a hydrolysis condensate of dimethyldimethoxysilane/diphenyl/dimethoxysilane γ-methacryloxytrimethoxysilane, or the like is preferable.

The content of the part of “—(Si(R¹)(R²)—O)ₙ—” in the silicone polymer (a (poly)siloxane structure unit represented by Formula (1)) is preferably from 15% by mass to 85% by mass, and more preferably in a range of from 20% by mass to 80% by mass, with respect to the total mass of the silicone polymer. When the content of the (poly)siloxane structure unit is 15% by mass or more, the strength of the surface of the first polymer layer improves, it is possible to prevent the occurrence of a flaw generated due to scratch, abrasion, collision of pebbles or the like which come flying, and it is possible to obtain excellent adhesive properties with a contacting material such as a second polymer layer. Weather resistance improves, and separation resistance and shape stability which easily deteriorates by giving heat or moisture, and adhesive durability when exposed under a wet heat environment are effectively enhanced, due to preventing the occurrence of a flaw. In addition, when the ratio of the (poly)siloxane structure unit is 85% by mass or less, it is possible to stably keep a liquid. In a case where the content of the (poly)siloxane structure unit is in a range of from 20% by mass to 80% by mass, these effects can be more remarkable.

In a case where the silicone polymer is a copolymerization polymer that has the (poly)siloxane structure unit and other structure unit, in one preferable embodiment, the silicone polymer can include 15% by mass to 85% by mass of the (poly)siloxane structure unit represented by Formula (1) described above and 85% by mass to 15% by mass of a non-siloxane structure unit as the mass ratio in the molecular chain thereof. By containing such a copolymerization polymer, the film strength of the first polymer layer improves, the occurrence of a flaw due to scratch, abrasion, or the like is prevented, and it is possible to dramatically improve adhesive properties with a polymer base which forms the support, in other words, separation resistance and shape stability which easily deteriorates by giving heat or moisture, and the durability under a wet heat environment, compared with those currently in use.

In a case where the silicone polymer is a copolymerization polymer that has the (poly)siloxane structure unit and other structure unit, the molecular weight of a part of “—(Si(R¹)(R²)—O)ₙ—” in the silicone polymer (a (poly)siloxane structure unit represented by Formula (1)) can be from approximately 30,000 to 1,000,000, and is preferably from approximately 50,000 to 300,000, as the weight average molecular weight in terms of polystyrene.

As the polymerization polymer described above, by copolymerizing a siloxane compound (polysiloxane is included in the range) with a compound selected from a non-siloxane monomer or a non-siloxane polymer, a block copolymer that has the (poly)siloxane structure unit represented by Formula (1) described above and the non-siloxane structure unit is preferable. In this case, the siloxane compound and the non-siloxane monomer or the non-siloxane polymer which is copolymerized may be respectively one kind alone or two or more kinds.

The non-siloxane structure unit (derived from the non-siloxane monomer or the non-siloxane polymer) copolymerized with the (poly)siloxane structure unit described above is not particularly limited except not having a siloxane structure, and may be either a structure unit derived from an arbitrary monomer or a polymer segment derived from an arbitrary polymer. As a polymer (a precursor polymer) which is a precursor of the polymer segment (a precursor polymer), for example, various kinds of polymers, and the like such as a vinyl polymer, a polyester polymer, and a polyurethane polymer are included.

Among these, a vinyl polymer and a polyurethane polymer are preferable, and a vinyl polymer is particularly preferable, from the point of easy preparation and excellent hydrolysis resistance.

As a representative example of the vinyl polymer described above, various kinds of polymers such as an acryl polymer, a carboxylic acid vinyl ester polymer, an aromatic vinyl polymer, a fluoroolefin polymer are included. Among these, an acryl polymer is particularly preferable, from the viewpoint of design flexibility. Examples of a monomer that configures an acryl polymer include a polymer that consists of an ester of acrylic acid (such as ethyl acrylate, butyl acrylate, hydroxyethyl acrylate, 2-ethylhexyl acrylate, or the like), and an ester of methacrylic acid (such as methyl methacrylate, butyl methacrylate, hydroxyethyl acrylate, glycidyl methacrylate, dimethylaminoethyl methacrylate, or the like) can be included. Furthermore, as a monomer, carboxylic acid such as acrylic acid, methacrylic acid and itaconic acid, styrene, acrylonitrile, vinyl acetate, acrylamide, divinyl benzene, and the like are included. Among these, ethyl acrylate, butyl acrylate, hydroxyethyl acrylate, 2-ethylhexyl acrylate methyl methacrylate, butyl methacrylate, hydroxyethyl acrylate, acrylic acid, methacrylic acid, or the like is preferable.

As a specific example of the acryl polymer, a methyl methacrylate/ethyl acrylate/acrylic acid copolymer, a methyl methacrylate/ethyl acrylate/2-hydroxyethyl methacrylate/methacrylic acid copolymer, a methyl methacrylate/butyl acrylate/2-hydroxyethyl methacrylate/methacrylic acid/γ-methacryloxytrimethoxysilane copolymer, a methyl methacrylate/ethyl acrylate/glycidyl methacrylate/acrylic acid copolymer, and the like are included.

The polymer which is the precursor of the polymer segment that configures the non-siloxane structure unit may be one kind alone or in combination of two or more kinds. Further, each polymer may be a homopolymer or a copolymer.

A molecular weight of the polymer which is the precursor of the polymer segment that configures the non-siloxane structure unit can be from approximately 3,000 to 1,000,000, and is more preferably from approximately 5,000 to 300,000, as the weight average molecular weight in terms of polystyrene.

The precursor polymer that forms the non-siloxane structure unit is preferably a precursor polymer that contains at least one of an acid group and a neutralized acid group and/or a hydrolysable silyl group. Among such a precursor polymer, a vinyl polymer, for example, it is possible to prepare by using various kinds of methods such as (a) a method in which a vinyl monomer that includes an acid group and a vinyl monomer that includes a hydrolysable silyl group and/or a silanol group are copolymerized with a monomer capable of copolymerizing these, (2) a method in which a vinyl polymer that includes a hydroxyl group, and a hydrolysable silyl group and/or a silanol group prepared in advance are reacted with a polycarboxylic acid anhydride, (3) a method in which a vinyl polymer that includes an acid anhydrous group, and a hydrolysable silyl group and/or a silanol group prepared in advance are reacted with a compound that has an active hydrogen (water, alcohol, amine, or the like).

The precursor polymer, for example, can be manufactured by using a method described in paragraph 0021 to 0078 of JP-A No. 2009-52011.

The silicone polymer may be used alone or used in combination of other polymers. In a case of using in combination of other polymers, the content of the polymer that includes the (poly)siloxane structure in the first polymer layer is preferably 30% by mass or more, and more preferably 60% by mass or more, with respect to the amount of the total binders included in the first polymer layer. By the content of the polymer that includes the (poly)siloxane structure being 30% by mass or more, it is possible to improve the strength of the surface of layer, to prevent the occurrence of a flaw due to scratch, abrasion, or the like, and also to obtain more excellent adhesive properties with a polymer base and durability under a wet heat environment.

The molecule weight of a silicone polymer is preferably from 5,000 to 100,000, and more preferably from 10,000 to 50,000.

For the preparation of the silicone polymer, a method such as (i) a method in which the precursor polymer is reacted with polysiloxane that has a structure unit represented by Formula (1), and (ii) a method in which a silane compound that has a structure unit represented by Formula (1) in which R¹ and/or R² are a hydrolyzable group is hydrolyzed and condensed in the presence of a precursor polymer can be used.

As a silane compound used in the method of (ii) described above, various kinds of silane compounds are included, however, an alkoxy silane compound is particularly preferable.

In a case of preparing the silicone polymer by the method of (i), for example, it is possible to prepare by adding water and a catalyse to the mixture of the precursor polymer and polysiloxane as necessary and reacting for approximately 30 minutes to 30 hours at a temperature from approximately 20° C. to 150° C., (preferably for 1 to 20 hours at 50° C. to 130° C.). As a catalyst, it is possible to add various kinds of silanol condensation catalysts such as an acidic compound, a basic compound, a metal-containing compound.

In addition, in a case of preparing the silicone polymer by the method of (ii), for example, it is possible to prepare by adding water and a silanol condensation catalyst to the mixture of the precursor polymer and an alkoxy silane compound and conducting hydrolysis condensation for approximately 30 minutes to 30 hours at a temperature of approximately 20° C. to 150° C. (preferably for 1 hour to 20 hours at 50° C. to 130° C.).

As a preferable example of the silicone polymer, a composite polymer in which the (poly)siloxane structure unit is consisted of either a hydrolysis condensate that contains a hydrolysis condensate of dimethyldimethoxysilane/γ-methacryloxytrimethoxysilane or a hydrolysis condensate of dimethyldimethoxysilane/diphenyl/dimethoxysilane γ-methacryloxytrimethoxysilane and a part of a polymer structure that copolymerizes with the (poly)siloxane structure unit is an acryl polymer that consists of a monomer component selected from ethyl acrylate, butyl acrylate, hydroxyethyl acrylate, 2-ethylhexyl acrylate, methyl methacrylate, butyl methacrylate, hydroxyethyl acrylate, acrylic acid and methacrylic acid is included, and as more preferable example, a composite polymer in which the (poly)siloxane structure unit is a hydrolysis condensate that contains a hydrolysis condensate of dimethyldimethoxysilane/γ-methacryloxytrimethoxysilane and an acryl polymer that consists of a monomer component selected from methyl methacrylate, ethyl acrylate, acrylic acid and methacrylic acid is included.

In addition, as a silicone polymer, a commercial product which is available in a market may be used, and, for example, CERANATE series manufactured by DIC Corporation [for example, CERANATE (registered trademark) WSA1070 (an acryl/silicone resin in which the content of the polysiloxane structure unit is 30% by mass), CERANATE (registered trademark) WSA1060 (the content of the polysiloxane structure unit is 75% by mass), or the like], H7600 series manufactured by Asahi Kasei Chemicals Corporation (H7650, H7630, H7620, or the like, all trade names), inorganic·acryl composite emulsion manufactured by JSR Corporation, or the like can be used.

—Other Binder—

In addition, a resin such as an acryl resin, a polyester resin, a polyurethane resin and a polyolefin resin except the fluorine polymer and the silicone polymer described above may be used in the first polymer layer at the range not exceeding 50% by mass of the total binders.

A content of the fluorine polymer and/or the silicone polymer to the total mass of the first polymer layer is preferably from 60% by mass to 95% by mass, even more preferably 75% by mass to 95% by mass, and particularly preferably from 80% by mass to 93% by mass.

The first polymer layer may be formed by adding a crosslinking agent, a surfactant, a filler, or the like, as necessary, or may be formed without adding.

Crosslinking Agent

Examples of the crosslinking agent which can be used in the first polymer layer, an epoxy crosslinking agent, an isocyanate crosslinking agent, a melamine crosslinking agent, a carbodiimide crosslinking agent, and an oxazoline crosslinking agent. Among these, a carbodiimide crosslinking agent and an oxazoline crosslinking agent are preferable. Examples of the carbodiimide crosslinking agent include CARBODILITE (registered trademark) V-02-L2 (manufactured by Nisshinbo Chemical Inc.), and examples of the oxazoline crosslinking agent include EPOCROS (registered trademark) WS-700 and EPOCROS (registered trademark) K-2020E (all manufactured by NIPPON SHOKUBAI CO., LTD.).

It is preferable that the first polymer layer include a crosslinked structure made by the crosslinking agent from the viewpoint of an improvement of adhesion with the contacting second polymer layer.

In a case where the first polymer layer includes a crosslinked structure made by the crosslinking agent, the first polymer layer preferably includes the crosslinked structure made by 0.5% by mass to 50% by mass of the crosslinking agent, more preferably includes the crosslinked structure made by 3% by mass to 30% by mass of the crosslinking agent, and even more preferably includes the crosslinked structure made by 5% by mass to 20% by mass of the crosslinking agent, with respect the mass of the main binder contained in the first polymer layer described above.

When the addition amount of the crosslinking agent is 0.5% by mass or more, it is possible to obtain a sufficient cross-linking effect while retaining the strength and adhesive properties of the first polymer layer, and when being 50% by mass or less, it is possible to keep a pot life of an application liquid for a long time.

As a crosslinked structure made by a crosslinking agent, a crosslinked structure derived from the carbodiimide crosslinking agent or the oxazoline crosslinking agent described above is preferable.

˜Surfactant˜

As a surfactant that can be used in the first polymer layer, a well-known surfactant such as an anionic surfactant and a nonionic surfactant can be used.

In a case of adding a surfactant to the first polymer layer, the addition amount thereof is preferably from 0.1 mg/m² to 15 mg/m², and more preferably from 0.5 mg/m² to 5 mg/m². When the addition amount of the surfactant is 0.1 mg/m² or more, it is possible to obtain excellent layer formation due to suppressing the occurrence of cis sing, and when being 15 mg/m² or less, it is possible to successfully perform adhesion.

˜Filler˜

A filler may be further added to the first polymer layer. Examples of the filler include a well-known filler such as colloidal silica or titanium dioxide. An addition amount of the filler is preferably 20% by mass or less, and more preferably 15% by mass or less, with respect to the total mass of the binder contained in the first polymer layer. When the addition amount of the filler is 20% by mass or less, it is possible to maintain excellent sheet of the first polymer layer.

˜Thickness˜

The thickness of the first polymer layer in the present invention is preferably in a range of from 0.8 μm to 12 μm, and particularly preferably in a range of from approximately 1.0 μm to 10 μm.

˜Position˜

The polymer sheet, which is one embodiment of the present invention, may further have another one or more layers disposed on the first polymer layer, although the first polymer layer is preferably an outermost layer of the polymer sheet from the viewpoint of improvements in durability, lightness, thinness, cost reduction, or the like of a protective sheet.

˜Method of Formation˜

The first polymer layer can be formed by coating, onto a second polymer layer described below, an application liquid which includes each component that configures the first polymer layer, and drying a coating film. After drying, the coating film may be cured by heating or the like. A method of application and a solvent for an application liquid are not particularly limited.

As a method of application, for example, a gravure coater or a bar coater can be used.

A solvent used in the application liquid may be water or an organic solvent such as toluene and methyl ethyl ketone. The solvent may be used one kind alone or may be used in combination of two or more kinds.

However, a method in which an aqueous application liquid in which a binder such as the fluorine polymer and the silicone polymer and the like are dispersed in water is formed and used for application is preferable. In this case, the content of water to the total mass of a solvent is preferably 60% by mass or more, and more preferably 80% by mass or more. It is preferable that 60% by mass or more of the solvent included in the application liquid that forms the first polymer layer is water since the environmental burden becomes small.

(Second Polymer Layer)

A polymer sheet according to one embodiment of the present invention has a second polymer layer that contacts the polymer support side of the first polymer layer. The roughness (Rz) of an interface between the first polymer layer and the second polymer layer is in a range of from 0.2 μm to 3.0 μm.

The second polymer layer is preferably a layer that contains at least a polymer that functions as a binder. The second polymer layer may be a layer that enhances adhesive properties between the polymer support and the first polymer layer, that is, may be a layer that functions as a so-called undercoat layer. Hereinafter, specific description will be given of the second polymer layer.

˜Particles in which the Volume Average Particle Diameter is in a Range of from 0.2 μM to 1.5 μm (Specific Particles)˜

The second polymer layer preferably contains particles in which the volume average particle diameter is in a range of from 0.2 μm to 1.5 μm (specific particles) as described above, from the viewpoint of regulating the roughness (Rz) of the interface.

Details of the kinds, the content, or the like of specific particles capable of being applied to the second polymer layer are as described above.

˜Binder˜

As a binder (a binding resin) that mainly configures the second polymer layer, for example, a polyester resin, a polyurethane resin, an acrylic resin, a polyolefin resin and/or a silicone resin (a silicone polymer), or the like can be used.

Among these, at least one selected from a group that consists of polyolefin, an acrylic resin and a silicone resin (a silicone polymer) is preferably included, from the viewpoint of ensuring high adhesive properties between the polymer support (base) described above and the first polymer layer described above, and a silicone resin (a silicone polymer) is more preferably included, from the viewpoint of weather resistance (the durability to ultraviolet rays, wet and heat, or the like). In addition, as a binder, a composite resin may be used, and for example, an acryl/silicone composite resin is also preferable.

As a silicone polymer which can be suitably contained in the second polymer layer, specifically, the same silicone polymer as the silicone polymer which can be contained in the first polymer layer can be suitably applied.

˜Other Additive Agent˜

The second polymer layer may be formed by adding a crosslinking agent, a surfactant, other filler except specific particles, or the like, as necessary, or may be formed without adding.

˜Crosslinking Agent˜

A crosslinking agent which may be included in the second polymer layer is the same as the crosslinking agent which may be included in the first polymer layer, including preferable aspects and specific examples thereof.

The second polymer layer preferably includes a crosslinked structure made by the crosslinking agent described above.

In a case where the second polymer layer described above includes the crosslinked structure made by the crosslinking agent, the second polymer layer preferably includes the crosslinked structure made by 0.5% by mass to 50% by mass of the crosslinking agent, more preferably includes the crosslinked structure made by 3% by mass to 30% by mass of the crosslinking agent, and even more preferably includes the crosslinked structure made by 5% by mass to 20% by mass of the crosslinking agent, with respect to the mass of the main binder contained in the second polymer layer. When the addition amount of the crosslinking agent is 0.5% by mass or more, with respect to the main binder of the second polymer layer, it is possible to obtain a sufficient crosslinking effect while maintaining the strength and adhesive properties of the second polymer layer, and when being 50% by mass or less, it is possible to keep a pot life of an application liquid for a long time.

The crosslinked structure made by the crosslinking agent is preferably a crosslinked structure derived from the carbodiimide crosslinking agent or the oxazoline crosslinking agent described above.

˜Surfactant˜

As a surfactant, a well-known surfactant such as an anionic surfactant or a nonionic surfactant can be used. In a case of adding the surfactant, an addition amount thereof is preferably from 0.1 mg/m² to 10 mg/m², and more preferably from 0.5 mg/m² to 3 mg/m². The addition amount of the surfactant is 0.1 mg/m² or more, it is possible to obtain excellent layer formation due to suppressing the occurrence of cissing, and when being 10 mg/m² or less, it is possible to successfully perform adhesion between the polymer support and the first polymer layer.

˜Other Filler˜

In addition, other filler which is not included in the specific particles described above may be further added to the second polymer layer, within the range of an effect of the present invention being not damaged. As the filler, a white pigment is preferable, colloidal silica or titanium dioxide is more preferably, and titanium dioxide is even more preferable.

˜Thickness˜

A thickness of the second polymer layer is preferably form 0.05 μm to 10 μm. When the thickness of the second polymer layer is 0.05 μm or more, the durability can be sufficient, and it is possible to ensure the sufficient adhesive force between the polymer support and the first polymer layer. When the thickness of the second polymer layer is 10 μm or less, the sheet is hardly deteriorated, and the adhesive force with the first polymer layer described above can be sufficient. When the thickness of the second polymer layer is in the range of from 0.05 μm to 10 μm, the durability and the sheet of the second polymer layer can be supported at the same time, it is possible to enhance adhesive properties between the polymer support and the first polymer layer, and the range from approximately 1.0 μm to 10 μm is particularly preferable.

˜Method of Formation˜

The second polymer layer can be formed by coating, onto the polymer support described above, the application liquid that includes each component such as a binder, and drying a coating film. After drying, the coating film may be cured by heating, or the like. A method of application and a solvent used in the application liquid are not particularly limited.

As a method of application, for example, a gravure coater or a bar coater can be used.

A solvent used in the application liquid may be water or an organic solvent such as toluene and methyl ethyl ketone. The solvent may be used one kind alone or may be used in combination of two or more kinds. A method of forming an aqueous application liquid that disperses a binder in water and applying this is preferable. In this case, the content of water to the total mass of the solvent is preferably 60% by mass or more, and more preferably 80% by mass or more.

In a case where the polymer support is a biaxially stretched film, after the application liquid for forming the second polymer layer on the polymer support after biaxially stretching is applied, a coating film may be dried, or a method of stretching in a different direction from the first stretching after the application liquid is applied on the polymer support after uniaxially stretching and the coating film is dried may be also acceptable. Further, after the application liquid is applied on the polymer support before stretching and the coating film is dried, the polymer support may be stretched in two directions.

The polymer sheet may have or may not have one or plural third layers except the first polymer layer and the second polymer layer, as necessary. For example, an undercoat layer can be provided between the polymer support and the second polymer layer. In addition, for example, a colored layer can be provided on the side opposite to the side of which the first polymer layer of the polymer support is provided.

(Undercoat Layer)

The thickness of an undercoat layer is preferably in a range of 2 μm or less, more preferably from 0.005 μm to 2 μm, and even more preferably from 0.01 μm to 1.5 μm. When the thickness is 0.005 μm or more, it is easy to avoid the occurrence of unevenness of coating, and when being 2 μm or less, the stickiness of the polymer support can be avoided and it is possible to obtain excellent suitability to processing.

The undercoat layer preferably contains one or more kinds of polymers selected from a group consisting of a polyolefin resin, an acrylic resin, a polyester resin, and a polyurethane resin.

Preferable examples of the polyolefin resin include a modified polyolefin copolymer. As the polyolefin resin, commercial product can be used, and for example, ARROW BASE (registered trademark) SE-1013N, ARROW BASE (registered trademark) SD-1010, ARROW BASE (registered trademark) TC-4010, ARROW BASE (registered trademark) TD-4010 (manufactured by UNITIKA LTD.), HYTEC S3148, HYTEC S3121, HYTEC S8512 (all trade names, manufactured by TOHO Chemical Industry Co., Ltd), CHEMIPEARL (registered trademark) S-120, CHEMIPEARL (registered trademark) S-75N, CHEMIPEARL (registered trademark) V100, CHEMIPEARL (registered trademark) EV210H (manufactured by Mitsui Chemicals, Inc.), and the like can be included. In one embodiment, ARROW BASE (registered trademark) SE-1013N (manufactured by UNITIKA LTD.) which is a ternary copolymer formed of a low density polyethylene, acrylic acid ester, and maleic anhydride, is preferably used.

Preferable examples of the acrylic resin include a polymer that contains polymethyl methacrylate, polyethyl acrylate, or the like. As the acrylic resin, commercial products can be used, and for example, AS-563A (trade name, manufactured by Daicel Finechem Ltd.) can be preferably used.

Preferable examples of the polyester resin include polyethylene terephthalate (PET), and polyethylene-2,6-naphthalate (PEN). As the polyester resin, commercial products may be used, and for example, VYLONAL (registered trademark) MD-1245 (manufactured by TOYOBO CO., LTD.) can be preferably used.

Preferable examples of the polyurethane resin include a carbonate urethane resin, and for example, SUPERFLEX (registered trademark) 460 (manufactured by DAI-ICHI KOGYO SEIYAKU CO., LTD.) can be preferably used.

Among these, the polyolefin resin is preferably used from the viewpoint of ensuring adhesive properties between the polymer support and the white layer. These polymers may be used alone or may be used in combination of two or more kinds. In a case of using in combination of two or more kinds, the combination of the acrylic resin and the polyolefin resin is preferable.

When the undercoat layer contains a crosslinking agent, durability of the undercoat layer can be improved. Examples of the crosslinking agent include an epoxy crosslinking agent, an isocyanate crosslinking agent, a melamine crosslinking agent, a carbodiimide crosslinking agent, and an oxazoline crosslinking agent. In one embodiment, the crosslinking agent included in the undercoat layer is preferably an oxazoline crosslinking agent. Examples of a crosslinking agent that includes an oxazoline group include EPOCROS (registered trademark) K2010E, EPOCROS (registered trademark) K2020E, EPOCROS (registered trademark) K2030E, EPOCROS (registered trademark) WS-500, and EPOCROS (registered trademark) WS-700 (all manufactured by NIPPON SHOKUBAI CO., LTD.).

The addition amount of the crosslinking agent is preferably from 0.5% by mass to 30% by mass, more preferably from 5% by mass to 20% by mass, and preferably 3% by mass or more and less than 15% by mass, with respect to the total mass of a binder that configures the undercoat layer. In particular, when the addition amount of the crosslinking agent is 0.5% by mass or more, it is possible to obtain a sufficient cross-linking effect while retaining the strength and adhesive properties of the undercoat layer, and when being 30% by mass or less, it is possible to keep a pot life of the application liquid for a long time, and when being less than 15% by mass, it is possible to improve an application sheet.

The undercoat layer preferably contains an anionic surfactant, a nonionic surfactant, or the like. The range of the surfactant that can be used in the undercoat layer is the same as the range of the surfactant that can be used in the white layer described above. Above all, a nonionic-base surfactant is preferable.

In a case of adding the surfactant, an addition amount thereof is preferably from 0.1 mg/m² to 10 mg/m², and more preferably from 0.5 mg/m² to 3 mg/m². When the addition amount of the surfactant is 0.1 mg/m² or more, it is possible to obtain excellent layer formation due to suppressing the occurrence of cissing, and when being 10 mg/m² or less, it is possible to successfully perform adhesion between the polymer support and the white layer.

The second polymer layer and the first polymer layer may be disposed in this order on a surface of the polymer support, the surface being provided with the undercoat layer.

A colored layer may be provided or may be not provided on a side opposite to the side of the polymer support on which the first polymer layer is provided.

(Colored Layer)

A colored layer contains at least a pigment and a binder, and may be configured by further including other components such as various kinds of additive agents, as necessary.

As a function of the colored layer, firstly, enhancing power generation efficiency of a solar cell module by reflecting light which does not used for a power generation due to having passed through a solar cell among incident light and reaches to a backsheet to return to the solar cell, secondly, improving external decorativeness the solar cell module in a case of viewing the solar cell module from the side on which sunlight is incident (the front surface side), and the like are included. Generally, when viewing the solar cell module from the front surface side (glass substrate side), the backsheet is seen around the solar cell, and since the decorativeness of the backsheet is improved by the polymer sheet for the backsheet being provided with the colored layer, it is possible to improve appearance.

˜Pigment˜

The colored layer can contain at least one kind of pigment.

As the pigment, for example, an inorganic pigment such as titanium dioxide, barium sulfate, silicon oxide, aluminum oxide, magnesium oxide, calcium carbonate, kaolin, talc, ultramarine blue, iron blue, and carbon black and/or an organic pigment such as phthalocyanine blue, phthalocyanine green can be arbitrarily selected to contain.

In a case where the colored layer is configured as a reflecting layer that reflects light that is incident on the solar cell and passes through the solar cell to return to the solar cell, among the pigments described above, it is preferable that a white pigment be used. As the white pigment, titanium dioxide, barium sulfate, silicon oxide, aluminum oxide, magnesium oxide, calcium carbonate, kaolin, talc, or the like is preferable, and titanium dioxide is more preferable.

The content in the colored layer of the pigment is preferably in a range of from 2.5 g/m² to 10.5 g/m². When the content of the pigment is 2.5 g/m² or more, it is possible to obtain the necessary coloration and effectively give the reflectance and the decorativeness. In addition, when the content of the pigment in the colored layer is 9.5 g/m² or less, excellent sheet of the colored layer is easily maintained and the film strength is more excellent. Above all, the content of the pigment is preferably in a range of from 4.5 g/m² to 9.0 g/m².

An average particle diameter of the pigment is preferably from 0.2 μm to 1.5 μm, and more preferably from approximately 0.3 μm to 0.6 μm, as the volume average particle diameter. When the average particle diameter is within the range described above, the reflection efficiency of light is high. The average particle diameter is a value which is measured by using a laser diffraction/scattering type particle size distribution measuring device LA950 (trade name, manufactured by HORIBA, Ltd).

As a binder that configures the colored layer, a polyester resin, a polyurethane resin, an acrylic resin, a polyolefin resin, a silicone resin, or the like can be used. Among these, an acrylic resin and a polyolefin resin are preferable, from the viewpoint of ensuring high adhesive properties. In addition, a composite resin may be used, and for example an acrylic/silicone composite resin is also preferable binder.

A content of the binder component described above is preferably in a range of from 15% by mass to 200% by mass, and more preferably in a range of from 17% by mass to 100% by mass, with respect to the pigment. When the content of the binder is 15% by mass or more, it is possible to sufficiently obtain the strength of the colored layer, and when being 200% by mass or less, it is possible to successfully maintain the reflectance and the decorativeness.

˜Additive Agent˜

A crosslinking agent, a surfactant, a filler, or the like may be added to the colored layer described above, as necessary.

(Easy Adhesive Layer)

It is also preferable that the polymer sheet be further provided with an easy adhesive layer. Particularly, the easy adhesive layer is preferably provided on the colored layer. The easy adhesive layer is a layer for strongly adhering a solar cell polymer sheet to a sealant (preferably EVA) that seals a solar cell element (hereinafter, also referred to as an electric power generating element) of a substrate on the cell side (a cell body).

The easy adhesive layer can be configured by using the binder and inorganic fine particles, and may be configured by further including other components such as an additive agent, as necessary. The easy adhesive layer is preferably configured so as to have 10 N/cm or more (preferably 20 N/cm or more) of the adhesive force, with respect to an ethylene-vinyl acetate (EVA) copolymer sealant that seals the electric power generating element of the substrate on the cell side. When the adhesive force is 10 N/cm or more, wet heat resistance that can maintain adhesive properties is easily obtained.

The adhesive force can beg adjusted by a method of adjusting the amount of the binder and inorganic fine particles in the easy adhesive layer, a method of conducting a corona treatment on the surface which adheres to a sealant of a solar cell protective sheet, or the like.

˜Binder˜

The easy adhesive layer can contain at least one kind of binder.

As a preferable binder for the easy adhesive layer, for example, polyester, polyurethane, an acrylic resin, polyolefin, and the like are included, and above all, an acrylic resin and polyolefin are preferably, from the viewpoint of the durability. In addition, as an acrylic resin, a composite resin of an acryl and a silicone is also preferable.

Examples of the preferable binder include: CHEMIPEARL (registered trademark) S-120 and CHEMIPEARL (registered trademark) S-75N (both manufactured by Mitsui Chemicals, Inc.) as a specific example of polyolefin; JURYMER (registered trademark) ET-410 and JURYMER (registered trademark) SEK-301 (both manufactured by Nihon Junyaku CO., LTD.) as a specific example of the acrylic resin; and CERANATE (registered trademark) WSA1060, CERANATE (registered trademark) WSA1070 (both manufactured by DIC Corporation), H7620, J7630, and H7650 (all trade names, manufactured by Asahi Kasei Chemicals Corporation) as a specific example of the composite resin of an acryl and a silicone.

A content of the binder in the easy adhesive layer is preferably set to a range from 0.05 g/m² to 5 g/m². Especially, a range from 0.08 g/m² to 3 g/m² is more preferable. When the content of the binder is 0.05 g/m² or more, the desired adhesive force is easily obtained, and when being 5 g/m² or less, an excellent sheet can be obtained.

˜Fine Particles˜

The easy adhesive layer can contain at least one kind of inorganic fine particles.

Examples of the inorganic fine particles include, silica, calcium carbonate, magnesium oxide, magnesium carbonate, and tin oxide. Above all, fine particles of tin oxide and silica are preferable, from the point of a small decrease in adhesive properties when being exposed to a wet heat atmosphere.

A particle diameter of the inorganic fine particles is preferably from approximately 10 nm to 700 nm, and more preferably from approximately 20 nm to 300 nm, as the volume average particle diameter. When the particle diameter is within this range, it is possible to obtain more excellent easy adhesive properties. The particle diameter is a value which is measured by using a laser diffraction/scattering type particle size distribution measuring device LA950 (trade name, manufactured by HORIBA, Ltd.).

A shape of inorganic fine particles is not particularly limited, and any of a spherical shape, an amorphous shape, a needle-shaped, or the like can be used.

A content of inorganic fine particles is set to the range from 5% by mass to 400% by mass, with respect to the binder in the easy adhesive layer. If the content of inorganic fine particles is less than 5% by mass, excellent adhesive properties may not be maintained when being exposed to a wet heat atmosphere, and when being over 400% by mass, the sheet of the easy adhesive layer is deteriorated.

Above all, the content of inorganic fine particles is preferably in a range of from 50% by mass to 300% by mass.

˜Crosslinking Agent˜

The easy adhesive layer can contain at least one kind of crosslinking agent.

Preferable examples of the crosslinking agent for the easy adhesive layer include an epoxy crosslinking agent, an isocyanate crosslinking agent, a melamine crosslinking agent, a carbodiimide crosslinking agent, and an oxazoline crosslinking agent. Above all, an oxazoline crosslinking agent is particularly preferable, from the viewpoint of ensuring adhesive properties after wet heat over time.

Specific examples of the oxazoline crosslinking agent include 2-vinyl-2-oxazoline, 2-vinyl-4-methyl-2-oxazoline, 2-vinyl-5-methyl-2-oxazoline, 2-isopropenyl-2-oxazoline, 2-isopropenyl-4-methyl-2-oxazoline, 2-isopropenyl-5-ethyl-2-oxazoline, 2,2′-bis-(2-oxazoline), 2,2′-methylene-bis-(2-oxazoline), 2,2′-ethylene-bis-(2-oxazoline), 2,2′-trimethylene-bis-(2-oxazoline), 2,2′-tetramethylene-bis-(2-oxazoline), 2,2′-hexamethylene-bis-(2-oxazoline), 2,2′-octamethylene-bis-(2-oxazoline), 2,2′-ethylene-bis-(4,4′-dimethyl-2-oxazoline), 2,2′-p-phenylene-bis-(2-oxazoline), 2,2′-m-phenylene-bis-(2-oxazoline), 2,2′-m-phenylene-bis-(4,4′-dimethyl-2-oxazoline), bis-(2-oxazolinyl cyclohexane)sulfide, and bis-(2-oxazolinyl norbornane)sulfide. In addition, a (co)polymer of these compounds is also preferably used.

In addition, as a compound that has an oxazoline group, EPOCROS (registered trademark) K2010E, EPOCROS (registered trademark) K2020E, EPOCROS (registered trademark) K2030E, EPOCROS (registered trademark) WS-500, EPOCROS (registered trademark) WS-700 (all manufactured by NIPPON SHOKUBAI CO., LTD.), or the like can be used.

A content of the crosslinking agent in the easy adhesive layer, is preferably from 5% by mass to 50% by mass, and more preferably from 20% by mass to 40% by mass, with respect to the binder in the easy adhesive layer. When the content of the crosslinking agent is 5% by mass or more, excellent crosslinking effect is obtained, and it is possible to keep the strength and adhesive properties of the colored layer, and when being 50% by mass or less, it is possible to keep a pot life of the application liquid for long time.

˜Additive Agent˜

A well-known matting agent such as polystyrene, polymethyl methacrylate, and silica, a well-known surfactant such as an anionic surfactant and a nonionic surfactant, or the like may be further added to the easy adhesive layer described above, as necessary.

˜Method of Forming an Easy Adhesive Layer˜

In a formation of the easy adhesive layer, a method of sticking the polymer sheet that has easy adhesive properties to the support or a method of coating is included. Above all, a method of coating is preferable, from the point of being easy as well as being capable of uniformly forming a thin film. As a method of coating, for example, a well-known method of application such as a gravure coater or a bar coater can be used. An application solvent used for the preparation of a coating liquid may be water or may be an organic solvent such as toluene and methyl ethyl ketone. The application solvent may be used one kind alone or may be used in combination of two or more kinds.

˜Physical Property˜

A thickness of the easy adhesive layer described above is not particularly limited, however, usually preferably from 0.05 μm to 8 μm, and more preferably in a range of from 0.1 μm to 5 μm. When the thickness of the easy adhesive layer is 0.05 μm or more, it is possible to suitably obtain the necessary easy adhesive properties, and when being 8 μm or less, the sheet becomes more excellent. The easy adhesive layer of the present invention is transparent in order not to reduce an effect of the colored layer.

<A Method of Manufacturing a Polymer Sheet for a Solar Cell>

A method of manufacturing a polymer sheet according to one embodiment of the present invention is not particularly limited, however, it is possible to suitably manufacture by the following method of manufacturing.

That is, a method of manufacturing a polymer sheet according to one embodiment of the present invention includes preparing a polymer support, forming a second polymer layer on the support (a process of forming a second polymer layer), and forming a first polymer layer on the second polymer layer (a process of forming a first polymer layer).

The first and second polymer layers are preferably formed by coating on the polymer support described above. That is, in a case where the first and second polymer layers are formed by coating, the formation of the second polymer layer includes applying an application liquid for forming the second polymer layer, and drying the application liquid, and the formation of the first polymer layer includes applying an application liquid for forming the first polymer layer, and drying the application liquid for forming the first polymer layer.

Before the first polymer layer is formed on the second polymer layer, the surface of the second polymer layer may be subjected to a surface treatment such as corona treatment, plasma discharge treatment, glow discharge treatment, or flame treatment.

In addition, after the first polymer layer is formed, adhesive properties after wet heat over time may be increased by curing the first polymer layer.

The polymer sheet according to one embodiment of the present invention, as described above, may contain one or plural third layers (an easy adhesive layer, or the like) except the first and second polymer layers, as necessary. Therefore, a method of manufacturing a polymer sheet according to one embodiment of the present invention may have one or plural processes of forming the third layer, in addition to the essential processes described above.

As an embodiment of a process of forming the third layer, for example, (1) a method of forming by coating an application liquid that contains components that configures the third layer onto the face to be formed (for example, the face opposite to the face on which the second polymer layer and the first polymer layer of the polymer support described above in the polymer sheet are formed) is included, and as an example thereof, the methods described before as the methods of forming the easy adhesive layer and the colored layer are included.

As a specific example of the polymer sheet according to one embodiment of the present invention formed by using such methods, a polymer sheet in which a reflecting layer that contains a white pigment is coated on the face opposite to the face on which the first polymer layer of the polymer sheet is formed, a polymer sheet in which a colored layer that contains a color pigment is coated on the face opposite to the face on which the first polymer layer of the polymer sheet is formed, a polymer sheet in which a reflecting layer and an easy adhesive layer that contains a white pigment are coated on the face opposite to the face on which the first polymer layer of the polymer sheet is formed, or the like is included.

As an example of an embodiment of a process of forming the third layer, (2) a method of sticking a sheet that has one layer or two or more layers that exert the desired function as the third layer onto the face to be formed is also included.

A sheet used in a case of applying the method (2) is a sheet that has one layer or two or more layers of the third layers, and as an example thereof, for example, a sheet in which a polymer film that contains a white pigment is stuck on the face opposite to the face on which the first polymer layer of the polymer sheet is formed, a sheet in which a colored film that contains a color pigment is stuck on the face opposite to the face on which the first polymer layer in the polymer sheet is formed, a sheet in which a polymer film that contains an aluminum thin film and a white pigment is stuck on the face opposite to the face on which the first polymer layer in the polymer sheet is formed, and a sheet that has a configuration as if a polymer film that has an inorganic barrier layer and a polymer film that contains a white pigment are stuck on the face opposite to the face on which the first polymer layer in the polymer sheet is formed are included.

As an example of an embodiment of a process of forming the third layer, as described before, being provided with an undercoat layer between the polymer support and the second polymer layer described above is also included.

As a method of being provided with an undercoat layer, a well-known coating method is arbitrarily adopted. For example, any methods such as a coating method using a reverse roll coater, a gravure coater, a rod coater, an air doctor coater, a spray or a brush can be used. In addition, a method may be conducted by immersing the polymer support in an aqueous liquid for forming the undercoat layer.

In one embodiment, the undercoat layer is preferably formed by a method that includes applying by coating compositions for forming the undercoat layer to the polymer support in a process of manufacturing the polymer support, a so-called in-line coat method, from the viewpoint of cost reduction.

Specific examples of this embodiment include a method including, in production of the polymer support that includes the undercoat layer, at least (1) supplying an unstretched sheet that includes a polymer that configures the polymer support, (2) stretching the unstretched sheet in one direction (a first direction) which is parallel to a face, on which the undercoat layer is to be formed, of the unstretched sheet (a first stretching), (3) applying a composition for forming an undercoat layer onto at least one surface of the sheet stretched in the first direction, and (4) stretching the sheet, to which the composition for forming an undercoat layer is applied, in a direction perpendicular to the first direction within the face for forming the undercoat layer (the second stretching).

More specific examples thereof include a method having (1)′ extruding a polymer for configuring a polymer support and casting the polymer on a cooling drum while using an electrostatic adhesion method or the like together to obtain an unstretched sheet, (2)′ stretching the unstretched sheet in a machine direction (MD), (3)′ coating an aqueous liquid for forming an undercoat layer onto one surface of the sheet stretched in the machine direction, and (4)′ stretching the sheet, to which the aqueous liquid for forming the undercoat layer is coated, in a traverse direction (TD).

The adhesion between the polymer support and the undercoat layer may be improved, uniformity of the undercoat layer may be enhanced, and the undercoat layer may be made thinner film shape, by forming the polymer support and the undercoat layer by a process of stretching the unstretched sheet at least once in one direction in advance to add compositions for forming the undercoat layer, and after this, stretching at least once in the direction perpendicular to the said direction in this manner.

Conditions of drying and heat treatment at the formation of the undercoat layer depend on a thickness of an application layer or conditions of a device, while it is preferable to feed the undercoat layer into the second stretching process immediately after coating and drying in the preheating zone of the second stretching process or the second stretching zone. In such a case, drying and heat treatment are usually conducted at approximately from 50° C. to 250° C.

Further, corona discharge treatment or other surface activation treatment may be conducted on the surface of the undercoat layer and on the surface of the polymer support.

A solid content concentration in an aqueous application liquid that can be used as compositions for forming the undercoat layer is preferably 30% by mass or less, and more preferably 10% by mass or less. A lower limit of the solid content concentration is preferably 1% by mass, more preferably 3% by mass, and even more preferably 5% by mass. The undercoat layer that has an excellent sheet can be formed according to the range describe above.

The second polymer layer and the first polymer layer can be formed in this order on the face provided with the undercoat layer of the polymer support.

<Solar Cell Module>

A solar cell module according to one embodiment of the present invention is configured by being provided with the polymer sheet according to one embodiment of the present invention described above as a backsheet.

As a preferable mode, a solar cell module configured by arranging a solar cell element which converts the optical energy of sunlight into electrical energy between a front substrate on which sunlight is incident and which has transparency and the backsheet according to one embodiment of the present invention described before, and by sealing and adhering the solar cell element between the front substrate and the backsheet by using a sealant such as an ethylene-vinyl acetate is included. That is, a cell structure part that has the solar cell element and a sealant that seals the solar cell element between the front substrate and the backsheet is provided.

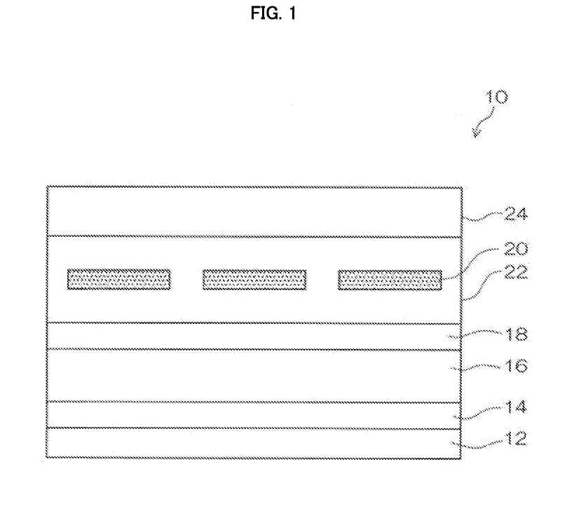

FIG. 1 schematically shows an exemplary aspect of a configuration of a solar cell module according to one embodiment of the present invention. This solar cell module 10 is configured by arranging a solar cell element 20 which converts the optical energy of sunlight into electrical energy between a front substrate 24 on which sunlight is incident and which has transparency and a protective sheet that consists of the polymer sheet according to one embodiment of the present invention, and sealing between the substrate and the protective sheet by using an ethylene-vinyl acetate sealant 22. In the protective sheet of an embodiment of this example, the first polymer layer 12 is provided in contact with the second polymer layer 14 on one face side of the polymer support 16 and a white reflecting layer 18 is provided on the other face side (the side on which sunlight is incident) as the third layer, however, the white reflecting layer 18, for example, may be arranged between the polymer support 16 and the easy adhesive layer (not shown). In one embodiment, it is preferable that the second polymer layer in the solar cell module also include functions of the reflecting layer, from the viewpoint of enhancing adhesion and wet heat durability of the entire solar cell protective sheet by decreasing the number of layers.

As to the members except a solar cell module, a solar cell and a solar cell protective sheet, for example, the details are described in “Sunlight power generating system constituent material” (under the supervision of Eiichi Sugimoto, Kogyo Chosakai Publishing Co., Ltd., 2008 published)

The substrate 24 which has transparency may have optical transparency in which sunlight can be transmitted therethrough, and can be arbitrarily selected from bases in which light is transmitted. Higher light transmission is preferable, from the viewpoint of power occurrence efficiency, and as such a substrate, for example, a transparent resin, or the like such as a glass substrate and an acryl resin can be suitably used.

As a solar cell element 20, various kinds of well-known solar cell elements such as silicon such as single crystal silicon, polycrystal silicon, amorphous silicon, III-V group and II-VI group compound semiconductor such as copper-indium-gallium-selenium, copper-indium-selenium, cadmium-tellurium, gallium-arsenic can be applied.

As long as the solar cell module 10 has such a configuration, since the first polymer layer that contains a fluorine polymer which is the outermost layer is provided through the second polymer layer on the back side and it is possible to have high durability as well as maintain high adhesive properties, it is possible to use for long term even outdoor.

### EXAMPLE

Hereinafter, characteristics of the present invention will be more specifically described by Examples.

The materials, use amounts, ratios, processing contents, processing procedures, and the like indicated in the Examples below may be changed as appropriate without departing from the gist of the present invention. Therefore, the scope of the present invention is not to be interpreted as being limited to the specific examples shown below.

Unless otherwise stated, “part(s)” is the proportion by mass.

“Rz”, which is an index for evaluating the roughness of an interface between the first polymer layer and the second polymer layer in the present invention, is defined by the measurement method described above. Any of notations as “Rz” in the following Examples and Comparative Examples indicates the roughness (Rz) of an interface between the first polymer and the second polymer layer, which is defined by the measurement method.

### Example 1

### Synthesis of Polyethylene Terephthalate

A slurry of 100 kg of high-purity terephthalic acid [manufactured by Mitsui Chemicals, Inc.] and 45 kg of ethylene glycol [manufactured by NIPPON SHOKUBAI CO., LTD.] was serially supplied into an esterification reaction tank in which about 123 kg of bis(hydroxyethyl)terephthalate was prepared in advance and which was maintained at a temperature of 250° C. and at a pressure of 1.2×10⁵ Pa over 4 hours. After the supply was finished, the esterification reaction was further conducted over 1 hour. Afterward, 123 kg of the obtained esterification reaction product was transferred to a polycondensation reaction tank.

Continuously, 0.3% by mass of ethylene glycol was added in the polycondensation reaction tank in which the esterification reaction product was transferred, with respect to the obtained polymer. After stirring for 5 minutes, an ethylene glycol solution of cobalt acetate and manganese acetate was added so as to be respectively 30 ppm and 15 ppm with respect to the obtained polymer. Further, after stirring for 5 minutes, 2% by mass of an ethylene glycol solution of a titanalkoxide compound was added so as to be 5 ppm with respect to the obtained polymer. As the titanalkoxide compound, a titanalkoxide compound (the content of Ti: 4.44% by mass) in which a synthesis method was described in Example 1 in paragraph [0083] of JP-A No. 2005-340616 was used. 5 minutes after the addition of the titanalkoxide compound, 10% by mass of an ethylene glycol solution of ethyl diethylphosphonoacetate was added so as to be 5 ppm with respect to the obtained polymer. Afterward, while the lower polymer was being stirred at 30 rpm, the reaction system was gradually heated up from 250° C. to 285° C. as well as the pressure was decreased to 40 Pa. A time until reaching to the final temperature and a time until the final pressure were both set to 60 minutes. At the point of reaching to the predetermined agitation torque, the reaction system was purged with nitrogen and was returned to atmospheric pressure, and the polycondensation reaction was stopped. Then, the resultant was discharged into the cold water to be in the strand shape and immediately cut so as to produce polymer pellets having a diameter of about 3 mm and a length of about 7 mm A time from starting the reduction of the pressure to reaching to the predetermined agitation torque was 3 hours.

### —Solid Polymerization—

The polyethylene terephthalate pellets which were polymerized were used for a solid polymerization by the following method (a batch method).

That is, after the pellets were put into a vacuum resistant vessel, the inside the vessel was evacuated and the solid polymerization was performed with stirring while maintaining for 20 hours at 210° C.

(Production of Polymer Support)

The obtained pellets was melt at 280° C. to cast on a metal drum to form a thickness of about 3 mm of an unstretched polymer support. The unstretched polymer support was subjected to a biaxial stretching by being stretched by 3.4 times in the machine direction at 90° C. and further stretched by 4.5 times in the traverse direction at 120° C. After the resultant was subjected to heat fixing at 200° C. for 30 seconds, thermal relaxation was performed for 10 seconds at 190° C. to produce a polymer support which is a polyethylene terephthalate film (a PET film) having a thickness of 240 μm.

(Formation of Second Polymer Layer)

### —Preparation of an Application Liquid for the Second Polymer Layer—

Each component as shown below was mixed to prepare an application liquid for a second polymer layer.

| | | |
|---|---|---|
| Polysiloxane-Acrylic hybrid latex | 39.6% | by mass |
| (CERANATE (registered trademark) WSA-1070, manufactured by DIC CORPORATION, | | |
| Solid content 40% by mass) | | |
| Polyoxyalkylene alkyl ether | 1.5% | by mass |
| (NAROACTY (registered trademark) CL-95, manufactured by Sanyo Chemical Industries, | | |
| Ltd., Solid content: 1% by mass) | | |
| Carbodiimide compound | 4.9% | by mass |
| (Carbodilite (registered trademark) V-02-L2, Nisshinbo Chemical Inc., Solid content: 20% by | | |
| mass) | | |
| Oxazoline compound | 1.7% | by mass |
| (EPOCROS (registered trademark) WS700, manufactured by NIPPON SHOKUBAI CO., | | |
| LTD., Solid content: 25% by mass) | | |
| Specific particles dispersion prepared as described below | 49.4% | by mass |
| Distilled water | up to the total amount of 100% | by mass |

Preparation of Specific Particles Dispersion

| | | |
|---|---|---|
| Titanium dioxide particle (white pigment, the volume average particle diameter of 0.3 μm) | 45.6% | by mass |
| (TIPAQUE (registered trademark) CL95, manufactured by ISHIHARA SANGYO KAISHA, | | |
| LTD., Solid content 100% by mass) | | |
| Polyvinyl alcohol | 22.8% | by mass |
| (trade name: PVA-105, manufactured by, KURARAY CO., LTD., Solid content 10% by mass) | | |
| Surfactant | 5.5% | by mass |
| (DEMOL (registered trademark) EP, manufactured by Kao Corporation, Solid content 25% by | | |
| mass) | | |
| Distilled water | up to the total amount of 100% | by mass |

Each component described above was mixed to prepare the specific particles dispersion by conducting dispersing treatment by using a dynomill disperser.

—Application of the Second Polymer Layer—

An application liquid of the second polymer layer obtained as described above was applied on one side of a PET film conducted surface treatment by corona discharge, the film was dried for 120 seconds at 170° C., and the second polymer layer in which the thickness was 8.5 μm was formed.

(Formation of First Polymer Layer)

Each component as shown below was mixed to prepare an application liquid for a first polymer layer. —Preparation of an Application Liquid for the First Polymer Layer that Contains a Fluorine Polymer—

| | | |
|---|---|---|
| Chlorotrifluoroethylene-vinyl ether copolymer | 34.5% | by mass |
| (Fluorine polymer, OBBLIGATO (registered trademark) SW0011F, manufactured by AGC | | |
| COAT-TECK CO., LTD., Solid content 39% by mass) | | |
| Polyoxyalkylene alkyl ether | 1.5% | by mass |
| (NAROACTY (registered trademark) CL-95, Sanyo Chemical Industries, Ltd., Solid content: | | |
| 1% by mass) | | |
| Carbodiimide compound | 6.2% | by mass |
| (CARBODILITE (registered trademark) V-02-L2, Nisshinbo Chemical Inc., Solid content: | | |
| 20% by mass) | | |
| Silica sol | 0.4% | by mass |
| (SNOWTEX (registered trademark) UP, manufactured by NISSAN CHEMICAL | | |
| INDUSTRIES, LTD., Solid content 20% by mass) | | |
| Silane coupling agent | 7.6% | by mass |
| (trade name: TSL8340, Momentive Performance Materials Inc., Solid content 1% by mass) | | |
| Polyolefin wax dispersion | 20.8% | by mass |
| (CHEMIPEARL (registered trademark) W950, manufactured by Mitsui Chemicals, Inc., Solid | | |
| content 5% by mass) | | |
| Distilled water | up to the total amount of 100% | by mass |

—Application of the First Polymer Layer—

By applying, on the second polymer layer subjected to the corona discharge surface treatment, the application liquid for the first polymer layer obtained as described above and drying the film for 120 seconds at 170° C., a first polymer layer having a thickness of 1.6 μm was formed, and thus a polymer sheet of Example 1 was produced.

Rz in the polymer sheet of Example 1 was 0.5 μm.

### Example 2

A polymer sheet of Example 2 was produced by forming the second polymer layer and the first polymer layer on the polymer support by the same method as Example 1, except that the specific particles (titanium dioxide particles) used in the second polymer layer were changed to particles having a volume average particle diameter of 0.2 μm (TIPAQUE (registered trademark) PF-691, manufactured by ISHIHARA SANGYO KAISHA, LTD., Solid content 100%).

Rz in the polymer sheet of Example 2 was 0.2 μm.

### Example 3

A polymer sheet of Example 3 was produced by forming the second polymer layer and the first polymer layer on the polymer support by the same method as Example 1, except that the specific particles (titanium dioxide particles) used in the second polymer layer were changed to particles having a volume average particle diameter of 0.6 μm.

Rz in the polymer sheet of Example 3 was 1.2 μm.

### Example 4

A polymer sheet of Example 4 was produced by forming the second polymer layer and the first polymer layer on the polymer support by the same method as Example 1, except that the specific particles (titanium dioxide particles) used in the second polymer layer were changed to particles having a volume average particle diameter of 1.5 μm.

Rz in the polymer sheet of Example 4 was 3.0 μm.

### Example 5

A polymer sheet of Example 5 was produced by forming the second polymer layer and the first polymer layer on the polymer support by the same method as Example 1, except that the specific particles (titanium dioxide particles) used in the second polymer layer were changed to polymethyl methacrylate resin particles (hereinafter, referred to as PMMA particles) (trade name: MP-2000, manufactured by Soken Chemical Engineering Co., Ltd., volume average particle diameter: 0.3 μm).

Rz in the polymer sheet of Example 5 was 0.5 μm.

### Example 6

A polymer sheet of Example 6 was produced by forming the second polymer layer and the first polymer layer on the polymer support by the same method as Example 5, except that the specific particles (PMMA particles) used in the second polymer layer were changed to particles having a volume average particle diameter of 0.2 μm.

Rz in the polymer sheet of Example 6 was 0.2 μm.

### Example 7

A polymer sheet of Example 7 was produced by forming the second polymer layer and the first polymer layer on the polymer support by the same method as Example 5, except that the specific particles (PMMA particles) used in the second polymer layer were changed to particles having a volume average particle diameter of 0.6 μm.

Rz in the polymer sheet of Example 7 was 1.2 μm.

### Example 8

A polymer sheet of Example 8 was produced by forming the second polymer layer and the first polymer layer on the polymer support by the same method as Example 5, except that the specific particles (PMMA particles) used in the second polymer layer were changed to particles having a volume average particle diameter of 1.5 μm.

Rz in the polymer sheet of Example 8 was 3.0 μm.

### Example 9

A polymer sheet of Example 9 was produced by forming the second polymer layer and the first polymer layer on the polymer support by the same method as Example 1, except that the fluorine polymer used in the first polymer layer was changed to a silicone polymer (CERANATE (registered trademark) WSA1070, manufactured by DIC CORPORATION).

Rz in the polymer sheet of Example 9 was 0.5 μm.

### Example 10

A polymer sheet of Example 10 was produced by forming the second polymer layer and the first polymer layer on the polymer support by the same method as Example 2, except that the fluorine polymer used in the first polymer layer was changed to a silicone polymer (CERANATE (registered trademark) WSA1070, manufactured by DIC CORPORATION).

Rz in the polymer sheet of Example 10 was 0.2 μm.

### Example 11

A polymer sheet of Example 11 was produced by forming the second polymer layer and the first polymer layer on the polymer support by the same method as Example 3, except that the fluorine polymer used in the first polymer layer was changed to a silicone polymer (CERANATE (registered trademark) WSA1070, manufactured by DIC CORPORATION).

Rz in the polymer sheet of Example 11 was 1.2 μm.

### Example 12

A polymer sheet of Example 12 was produced by forming the second polymer layer and the first polymer layer on the polymer support by the same method as Example 4, except that the fluorine polymer used in the first polymer layer was changed to a silicone polymer (CERANATE (registered trademark) WSA1070, manufactured by DIC CORPORATION).

Rz in the polymer sheet of Example 12 was 3.0 μm.

### Example 13

A polymer sheet of Example 13 was produced by forming the second polymer layer and the first polymer layer on the polymer support by the same method as Example 5, except that the fluorine polymer used in the first polymer layer was changed to a silicone polymer (CERANATE (registered trademark) WSA1070, manufactured by DIC CORPORATION).

Rz in the polymer sheet of Example 13 was 0.5 μm.

### Example 14

A polymer sheet of Example 14 was produced by forming the second polymer layer and the first polymer layer on the polymer support by the same method as Example 6, except that the fluorine polymer used in the first polymer layer was changed to a silicone polymer (CERANATE (registered trademark) WSA1070, manufactured by DIC CORPORATION).

Rz in the polymer sheet of Example 14 was 0.2 μm.

### Example 15

A polymer sheet of Example 15 was produced by forming the second polymer layer and the first polymer layer on the polymer support by the same method as Example 7, except that the fluorine polymer used in the first polymer layer was changed to a silicone polymer (CERANATE (registered trademark) WSA1070, manufactured by DIC CORPORATION).

Rz in the polymer sheet of Example 15 was 1.2 μm.

### Example 16

A polymer sheet of Example 16 was produced by forming the second polymer layer and the first polymer layer on the polymer support by the same method as Example 8, except that the fluorine polymer used in the first polymer layer was changed to a silicone polymer (CERANATE (registered trademark) WSA1070, manufactured by DIC CORPORATION).

Rz in the polymer sheet of Example 16 was 3.0 μm.

### Example 17

A polymer sheet of Example 17 was produced by the same method as Example 1, except that the polymer support was formed by stretching the unstretched polymer support by 3.4 times in the MD, applying thereto an undercoat layer application liquid having a composition described below, and then stretching the resultant by 4.5 times in the TD. A thickness of the undercoat layer after stretching was 0.1 μm.

Rz in the polymer sheet of Example 17 was 0.5 μm.

### <Undercoat Layer Application Liquid>

| | | |
|---|---|---|
| Polyolefin binder | 24.12 | parts by mass |
| (ARROW BASE (registered trademark) SE-1013N, manufactured by UNITIKA LTD., | | |
| Concentration 20% by mass) | | |
| Oxazoline crosslinking agent | 3.90 | parts by mass |
| (EPOCROS (registered trademark) WS-700, manufactured by NIPPON SHOKUBAI CO., | | |
| LTD., Concentration 25% by mass) | | |
| Fluorine surfactant | 0.19 | parts by mass |
| (Sodium bis(3,3,4,4,5,5,6,6-octafluoro)-2-sulfoniteoxysuccinate, manufactured by SANKYO | | |
| CHEMICAL CO., LTD., Concentration 1% by mass) | | |
| Distilled water | 71.80 | parts by mass |

### Examples 18 to 21-1

Polymer sheets of Examples 18 to 21-1 were produced by the same method as Example 1, except that a synthesis of the polyethylene terephthalate and a method of producing the polymer support were performed by methods shown below.

Any of the Rz's in the polymer sheets of Examples 18 to 21 were 0.5 μm.

### <Synthesis of Polyethylene Terephthalate>

100 parts by mass of dimethyl terephthalate, 61 parts by mass of ethylene glycol, and 0.06 parts by mass of magnesium acetate tetrahydrate were put into a transesterification vessel, heated at 150° C., melted, and stirred. The reaction progressed as the temperature inside the reaction vessel was slowly heated up to 235° C., and methanol generated was distilled to outside the reaction vessel. When the distillation of methanol was finished, 0.02 parts by mass of trimethyl phosphate was added. After trimethyl phosphate was added, 0.03 parts by mass of antimony trioxide was added and the reactant was transferred into a polymerization device. Then, the temperature inside the polymerization device was heated up from 235° C. to 290° C. over 90 minutes, and at the same time, the pressure inside the device was reduced from the atmospheric pressure to 100 Pa over 90 minutes. When the agitation torque of the content of the polymerization device reached to a predetermined value, the inside of the device was returned to the atmospheric pressure by using nitrogen gas to finish the polymerization. A bulb of the lower part of the polymerization device was opened to increase a pressure on the inside of the polymerization device by using nitrogen gas. Polyethylene terephthalate, the polymerization of which was completed, was discharged into water to be formed into a strand shape. The strand was made into a chip by a cutter. In this manner, PET that has an intrinsic viscosity IV=0.58 and an acid value (AV)=12 was obtained. This was named as PET-A.

### <Solid Polymerization of Polyester>

After PET-A was pre-dried at 150° C. to 160° C. for 3 hours, a solid polymerization was performed at 205° C. for 25 hours under 100 Torr of a nitrogen gas atmosphere to obtain PET-B.

<Manufacture of Master Pellets that Includes Polyester and a Terminal Sealing Agent>

90 parts by mass of PET-B and 10 parts by mass of the following compound as a terminal sealing agent were blended, the obtained mixture was supplied with a twin screw kneader to melt and knead at 280° C., and this was discharged into water in the strand shape and made into a chip by being cut with a cutter. This was named as PET-C.

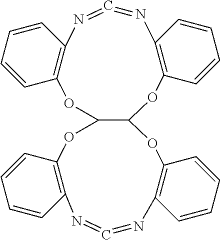 [SMILES: C1=Nc2ccccc2OC2Oc3ccccc3N=C=Nc3ccccc3OC2Oc2ccccc2N=1]

### <Film Formation of Polyester Film>

After drying at 180° C. for 3 hours, PET-B and PET-C were mixed so that a content of the terminal sealing material becomes the amount shown in Table 1 and put into an extruder and kneaded at 280° C. After being passed through a gear pump and a filter, the kneaded material was extruded on a cooling drum which is at 25° C. and to which a static electricity is applied from T-die to be cooled and solidified to obtain an unstretched sheet. The unstretched polymer support was subjected to an biaxial stretching by stretching it by 3.4 times in the machine direction at 90° C. and further stretching it by 4.5 times in the traverse direction at 120° C., heat fixed at 200° C. for 30 seconds, and thermal relaxation at 190° C. for 10 seconds, to produce a polymer support which is a polyethylene terephthalate film (a PET film) having a thickness of 240 μm.

### Example 21-2

50% by mass of a fraction with respect to the total mass of a polyethylene terephthalate resin of Example 1 was dried under the conditions of at 120° C., for about 8 hours, and 10⁻³ Torr in advance. A polymer sheet of Example 21-1 was produced by the same method as Example 1, except that fine particles (titanium oxide)-containing pellets were prepared by mixing the fraction with the same amount of rutile-type titanium dioxide that has an average particle diameter of 0.3 μm based on a measured value by an electron microscopy described above, supplying the obtained mixture with a vent-type twin screw extruder, and extruding the mixture at 275° C. with kneading and deaerating.

Rz in the polymer sheet of Example 21 was 0.5 μm.

### Example 22

A polymer sheet of Example 22 was produced by the same method as Example 1, except that the surface treatment of a PET film was performed by glow discharge treatment as shown below instead of corona discharging.

Rz in the polymer sheet of Example 22 was 0.5 μm.

### <Glow Discharge Treatment>

After heating up to 145° C. by using a heating roll, the polyethylene terephthalate film was subjected to glow discharge treatment under conditions of a treatment atmospheric pressure of 0.2 Torr, a discharge frequency of 30 kHz, an output of 5,000 w and a strength of the discharge treatment of 4.2 kV·A·minutes/m².

### Comparative Example 1

A polymer sheet of Comparative Example 1 was produced by forming the second polymer layer and the first polymer layer on the polymer support by the same method as Example 1, except that the specific particles (titanium dioxide particles) used in the second polymer layer were changed to polysiloxane-acrylic hybrid latexes.

Rz in the polymer sheet of Comparative Example 1 was 0.05 μm.

### Comparative Example 2

A polymer sheet of Comparative Example 2 was produced by forming the second polymer layer and the first polymer layer on the polymer support by the same method as Example 1, except that the specific particles (titanium dioxide particles) used in the second polymer layer were changed to particles having a volume average particle diameter of 0.1 μm.

Rz in the polymer sheet of Comparative Example 2 was 0.1 μm.

### Comparative Example 3

A polymer sheet of Comparative Example 3 was produced by forming the second polymer layer and the first polymer layer on the polymer support by the same method as Example 1, except that the specific particles (titanium dioxide particles) used in the second polymer layer were changed to particles having a volume average particle diameter of 2.0 μm.

Rz in the polymer sheet of Comparative Example 3 was 3.6 μm.

### Comparative Example 4

A polymer sheet of Comparative Example 4 was produced by forming the second polymer layer and the first polymer layer on the polymer support by the same method as Example 13, except that the specific particles (PMMA particles) used in the second polymer layer were changed to polysiloxane-acrylic hybrid latexes.

Rz in the polymer sheet of Comparative Example 4 was 0.05 μm.

### Comparative Example 5

A polymer sheet of Comparative Example 5 was produced by forming the second polymer layer and the first polymer layer on the polymer support by the same method as Example 13, except that the PMMA particles used in the second polymer layer were changed to particles having a volume average particle diameter of 0.1 μm.

Rz in the polymer sheet of Comparative Example 5 was 0.1 μm.

### Comparative Example 6

A polymer sheet of Comparative Example 6 was produced by forming the second polymer layer and the first polymer layer on the polymer support by the same method as Example 13, except that the specific particles (PMMA particles) used in the second polymer layer were changed to particles having a volume average particle diameter of 2.0 μm.

Rz in the polymer sheet of Comparative Example 6 was 3.6 μm.

(Evaluation)

Polymer sheets produced in Examples and Comparative Examples described above were subjected to evaluations described below. Evaluation results are shown in Table 1.

—Evaluation of Adhesive Properties—

### (1) Adhesion Before Time Lapse Under Wet-Heat (Fresh)

25 squares were formed on a surface of a side on which the first and second polymer layers of each polymer sheet obtained in Examples 1 to 22 and Comparative Examples 1 to 6 were formed by respectively scratching 6 lines in height and width at 3 mm intervals using a razor. A MYLAR TAPE having a width of 20 mm (a polyester tape manufactured by NITTO DENKO CORPORATION) was stuck thereon to and removed therefrom by quickly pulling in 180-degree direction. At this time, adhesion of the polymer layer was evaluated and ranked according to a number of squares that were separated in accordance with the following standard.

### <Evaluation Standard>

5: Separation does not occur at all.
4: There is no squares separated, although the scratch part is slightly separated.
3: The square separated is less than one square.
2: The squares exfoliated are one square or more and less than 5 squares.
1: The squares exfoliated are 5 squares or more.

Practical allowances are classified in the evaluation ranks from 3 to 5.

(2) Adhesion after Time Lapse Under Wet-Heat

Each polymer sheet that was obtained in Examples 1 to 22 and Comparative Examples 1 to 6 was left to stand for 60 hours under an environment of the pressure cooker test (an environment of at 120° C., 100% RH and 1.2 Mpa).

Each polymer sheet that was obtained in Examples 1 to 22 and Comparative Examples 1 to 6 was left to stand for 2,000 hours under an environment of the dump heat test (an environment of at 85° C. and 85% RH).

After leaving to stand in the pressure cooker test and the dump heat test, 25 squares were formed on the surface of the side of each polymer sheet on which the first and second polymer layers were formed by respectively scratching 6 lines in height and width at 3 mm intervals using a razor. A MYLAR TAPE having a width of 20 mm (a polyester tape manufactured by NITTO DENKO CORPORATION) was stuck thereon and removed therefrom by quickly pulling in 180-degree direction. At this time, adhesion of the polymer layer was evaluated and ranked according to a number of squares that were separated in accordance with the same evaluation standard as the evaluation in the “(1) Adhesion after time lapse under wet-heat”.

TABLE 1

| | Support polymer layer | | | | | | | | |
|---|---|---|---|---|---|---|---|---|---|
| | | | | | Addition amount | | | | |
| | | | | Heat fixing | of terminal sealing | | Surface | Second polymer layer | |
| | | Solid | Thickness | temperature | agent (with respect | | treatment | Main | Particles |
| | Catalyst | polymerization | [μm] | [° C.] | to polyester) | Particle | Type | binder | Type |
| Example 1 | Ti | Done | 240 | 200 | None | None | Corona | Silicon | Titanium |
| | | | | | | | | Polymer | dioxide |
| Example 2 | Ti | Done | 240 | 200 | None | None | Corona | Silicon | Titanium |
| | | | | | | | | Polymer | dioxide |
| Example 3 | Ti | Done | 240 | 200 | None | None | Corona | Silicon | Titanium |
| | | | | | | | | Polymer | dioxide |
| Example 4 | Ti | Done | 240 | 200 | None | None | Corona | Silicon | Titanium |
| | | | | | | | | Polymer | dioxide |
| Example 5 | Ti | Done | 240 | 200 | None | None | Corona | Silicon | PMMA |
| | | | | | | | | Polymer | |
| Example 6 | Ti | Done | 240 | 200 | None | None | Corona | Silicon | PMMA |
| | | | | | | | | Polymer | |
| Example 7 | Ti | Done | 240 | 200 | None | None | Corona | Silicon | PMMA |
| | | | | | | | | Polymer | |
| Example 8 | Ti | Done | 240 | 200 | None | None | Corona | Silicon | PMMA |
| | | | | | | | | Polymer | |
| Example 9 | Ti | Done | 240 | 200 | None | None | Corona | Silicon | Titanium |
| | | | | | | | | Polymer | dioxide |
| Example 10 | Ti | Done | 240 | 200 | None | None | Corona | Silicon | Titanium |
| | | | | | | | | Polymer | dioxide |
| Example 11 | Ti | Done | 240 | 200 | None | None | Corona | Silicon | Titanium |
| | | | | | | | | Polymer | dioxide |
| Example 12 | Ti | Done | 240 | 200 | None | None | Corona | Silicon | Titanium |
| | | | | | | | | Polymer | dioxide |
| Example 13 | Ti | Done | 240 | 200 | None | None | Corona | Silicon | PMMA |
| | | | | | | | | Polymer | |
| Example 14 | Ti | Done | 240 | 200 | None | None | Corona | Silicon | PMMA |
| | | | | | | | | Polymer | |
| Example 15 | Ti | Done | 240 | 200 | None | None | Corona | Silicon | PMMA |
| | | | | | | | | Polymer | |
| Example 16 | Ti | Done | 240 | 200 | None | None | Corona | Silicon | PMMA |
| | | | | | | | | Polymer | |
| Example 17 | Ti | Done | 240 | 200 | None | None | Corona | Silicon | Titanium |
| | | | | | | | | Polymer | dioxide |
| Example 18 | Ti | Done | 240 | 200 | 0.1%-added | None | Corona | Silicon | Titanium |
| | | | | | | | | Polymer | dioxide |
| Example 19 | Ti | Done | 240 | 200 | 1%-added | None | Corona | Silicon | Titanium |
| | | | | | | | | Polymer | dioxide |
| Example 20 | Ti | Done | 240 | 200 | 10%-added | None | Corona | Silicon | Titanium |
| | | | | | | | | Polymer | dioxide |
| Example 21-1 | Ti | Done | 240 | 200 | 12%-added | None | Corona | Silicon | Titanium |
| | | | | | | | | Polymer | dioxide |
| Example 21-2 | Ti | Done | 240 | 200 | None | Added | Corona | Silicon | Titanium |
| | | | | | | | | Polymer | dioxide |
| Example 22 | Ti | Done | 240 | 200 | None | None | Glow | Silicon | Titanium |
| | | | | | | | discharge | Polymer | dioxide |
| Comparative | Ti | Done | 240 | 200 | None | None | Corona | Silicon | None |
| Example 1 | | | | | | | | Polymer | |
| Comparative | Ti | Done | 240 | 200 | None | None | Corona | Silicon | Titanium |
| Example 2 | | | | | | | | Polymer | dioxide |
| Comparative | Ti | Done | 240 | 200 | None | None | Corona | Silicon | Titanium |
| Example 3 | | | | | | | | Polymer | dioxide |
| Comparative | Ti | Done | 240 | 200 | None | None | Corona | Silicon | None |
| Example 4 | | | | | | | | Polymer | |
| Comparative | Ti | Done | 240 | 200 | None | None | Corona | Silicon | PMMA |
| Example 5 | | | | | | | | Polymer | |
| Comparative | Ti | Done | 240 | 200 | None | None | Corona | Silicon | PMMA |
| Example 6 | | | | | | | | Polymer | |

| | Second polymer layer | | | Roughness | | | |
|---|---|---|---|---|---|---|---|
| | Particles | | Surface | of Interface | First polymer layer | | |
| | Volume average | Film | treatment | Rz [μm] calculated | | Film | |
| | particle diameter | thickness | Corona | from a cross | Main | thickness | Undercoat |
| | [μm] | [μm] | treatment | section picture | binder | [μm] | layer |
| Example 1 | 0.3 | 8.5 | Done | 0.5 | Fluorine | 1.6 | None |
| | | | | | Polymer | | |
| Example 2 | 0.2 | 8.5 | Done | 0.2 | Fluorine | 1.6 | None |
| | | | | | Polymer | | |
| Example 3 | 0.6 | 8.5 | Done | 1.2 | Fluorine | 1.6 | None |
| | | | | | Polymer | | |
| Example 4 | 1.5 | 8.5 | Done | 3.0 | Fluorine | 1.6 | None |
| | | | | | Polymer | | |
| Example 5 | 0.3 | 8.5 | Done | 0.5 | Fluorine | 1.6 | None |
| | | | | | Polymer | | |
| Example 6 | 0.2 | 8.5 | Done | 0.2 | Fluorine | 1.6 | None |
| | | | | | Polymer | | |
| Example 7 | 0.6 | 8.5 | Done | 1.2 | Fluorine | 1.6 | None |
| | | | | | Polymer | | |
| Example 8 | 1.5 | 8.5 | Done | 3.0 | Fluorine | 1.6 | None |
| | | | | | Polymer | | |
| Example 9 | 0.3 | 8.5 | Done | 0.5 | Silicon | 1.6 | None |
| | | | | | Polymer | | |
| Example 10 | 0.2 | 8.5 | Done | 0.2 | Silicon | 1.6 | None |
| | | | | | Polymer | | |
| Example 11 | 0.6 | 8.5 | Done | 1.2 | Silicon | 1.6 | None |
| | | | | | Polymer | | |
| Example 12 | 1.5 | 8.5 | Done | 3.0 | Silicon | 1.6 | None |
| | | | | | Polymer | | |
| Example 13 | 0.3 | 8.5 | Done | 0.5 | Silicon | 1.6 | None |
| | | | | | Polymer | | |
| Example 14 | 0.2 | 8.5 | Done | 0.2 | Silicon | 1.6 | None |
| | | | | | Polymer | | |
| Example 15 | 0.6 | 8.5 | Done | 1.2 | Silicon | 1.6 | None |
| | | | | | Polymer | | |
| Example 16 | 1.5 | 8.5 | Done | 3.0 | Silicon | 1.6 | None |
| | | | | | Polymer | | |
| Example 17 | 0.3 | 8.5 | Done | 0.5 | Fluorine | 1.6 | Present |
| | | | | | Polymer | | (coated between |
| | | | | | | | stretchings) |
| Example 18 | 0.3 | 8.5 | Done | 0.5 | Fluorine | 1.6 | None |
| | | | | | Polymer | | |
| Example 19 | 0.3 | 8.5 | Done | 0.5 | Fluorine | 1.6 | None |
| | | | | | Polymer | | |
| Example 20 | 0.3 | 8.5 | Done | 0.5 | Fluorine | 1.6 | None |
| | | | | | Polymer | | |
| Example 21-1 | 0.3 | 8.5 | Done | 0.5 | Fluorine | 1.6 | None |
| | | | | | Polymer | | |
| Example 21-2 | 0.3 | 8.5 | Done | 0.5 | Fluorine | 1.6 | None |
| | | | | | Polymer | | |
| Example 22 | 0.3 | 8.5 | Done | 0.5 | Fluorine | 1.6 | None |
| | | | | | Polymer | | |
| Comparative | — | 8.5 | Done | 0.05 | Fluorine | 1.6 | None |
| Example 1 | | | | | Polymer | | |
| Comparative | 0.1 | 8.5 | Done | 0.1 | Fluorine | 1.6 | None |
| Example 2 | | | | | Polymer | | |
| Comparative | 2.0 | 8.5 | Done | 3.6 | Fluorine | 1.6 | None |
| Example 3 | | | | | Polymer | | |
| Comparative | — | 8.5 | Done | 0.05 | Silicon | 1.6 | None |
| Example 4 | | | | | Polymer | | |
| Comparative | 0.1 | 8.5 | Done | 0.1 | Silicon | 1.6 | None |
| Example 5 | | | | | Polymer | | |
| Comparative | 2.0 | 8.5 | Done | 3.6 | Silicon | 1.6 | None |
| Example 6 | | | | | Polymer | | |

| | Solar cell protective sheet | | |
|---|---|---|---|
| | Cross out adhesion | | |
| | | Pressure cooker test | Dump heat test |
| | Fresh | 120° C., 100%, 12 Mpa, 60 h | 85° C., 85%, 2,000 h |
| Example 1 | 5 | 4 | 4 |
| Example 2 | 5 | 3 | 3 |
| Example 3 | 5 | 4 | 4 |
| Example 4 | 5 | 3 | 3 |
| Example 5 | 5 | 4 | 4 |
| Example 6 | 5 | 3 | 3 |
| Example 7 | 5 | 4 | 4 |
| Example 8 | 5 | 3 | 3 |
| Example 9 | 5 | 4 | 4 |
| Example 10 | 5 | 3 | 3 |
| Example 11 | 5 | 4 | 4 |
| Example 12 | 5 | 3 | 3 |
| Example 13 | 5 | 4 | 4 |
| Example 14 | 5 | 3 | 3 |
| Example 15 | 5 | 4 | 4 |
| Example 16 | 5 | 3 | 3 |
| Example 17 | 5 | 5 | 4 |
| Example 18 | 5 | 4 | 5 |
| Example 19 | 5 | 5 | 5 |
| Example 20 | 5 | 5 | 4 |
| Example 21-1 | 5 | 3 | 3 |
| Example 21-2 | 5 | 4 | 4 |
| Example 22 | 5 | 4 | 5 |
| Comparative | 5 | 1 | 1 |
| Example 1 | | | |
| Comparative | 5 | 2 | 2 |
| Example 2 | | | |
| Comparative | 5 | 1* | 1* |
| Example 3 | | | |
| Comparative | 5 | 1 | 1 |
| Example 4 | | | |
| Comparative | 4 | 2 | 2 |
| Example 5 | | | |
| Comparative | 5 | 1* | 1* |
| Example 6 | | | |

As shown in Table 1, it is understood that each polymer sheet of Example has excellent adhesion either before time lapse under wet-heat (Fresh) or after time lapse under wet-heat.

In Table 1, “1*”, which is a result of the adhesion evaluation after time lapse under wet-heat as to the polymer sheets in Comparative Example 3 and Comparative Example 6, indicates that film separation occurs due to sticking particles contained in the second polymer layer out to the first polymer layer which is an outermost layer after time lapse under wet-heat.

### Example 23

### Production of a Backsheet for a Solar Cell

### <Preparation of an Application Liquid for an Undercoat Layer>

### —Preparation of an Undercoat Layer—

Components in the compositions described below were mixed to prepare an application liquid for an undercoat layer.

### <Composition of an Application Liquid for an Undercoat Layer>

| | | |
|---|---|---|
| Polyster resin | 1.7% | by mass |
| (VYLONAL (registered trademark) MD-1200, manufactured by TOYOBO CO., LTD., Solid | | |
| content: 17% by mass) | | |
| Polyster resin | 3.8% | by mass |
| (Trade name: PESRESIN A-520, manufactured by TAKAMATSU OIL & FAT CO., LTD., | | |
| Solid content: 30% by mass) | | |
| Polyoxyalkylene alkyl ether | 1.5% | by mass |
| (NAROACTY (registered trademark) CL95, manufactured by Sanyo Chemical Industries, | | |
| Ltd., Solid content: 1% by mass) | | |
| Inorganic oxide filler | 1.6% | by mass |
| (SNOWTEX (registered trademark) C, manufactured by NISSAN CHEMICAL | | |
| INDUSTRIES, LTD., Solid content: 20% by mass) | | |
| Carbodiimide compound | 4.3% | by mass |
| (CARBODILITE (registered trademark) V-02-L2, manufactured by Nisshinbo Chemical Inc., | | |
| Solid content: 10% by mass, a crosslinking agent) | | |
| Distilled water | 87.1% | by mass |

<Preparation of an Application Liquid for a White Pigment Layer>

### —Preparation of White Pigment Dispersion—

Components in the compositions described below were mixed and dispersing treatment was conducted for the mixture thereof by using a dynomill type disperser for 1 hour.

### <Composition of Pigment Dispersion>

| | | |
|---|---|---|
| Titanium dioxide (the volume average particle diameter = 0.42 μm) | 44.9% | by mass |
| (TIPAQUE (registered trademark) R-780-2, manufactured by ISHIHARA SANGYO | | |
| KAISHA, LTD., Solid content 100% by mass) | | |
| Polyvinyl alcohol | 8.0% | by mass |
| (trade name: PVA-105, manufactured by KURARAY CO., LTD., Solid content: 10% by mass) | | |
| Surfactant | 0.5% | by mass |
| (DEMOL (registered trademark) EP, manufactured by Kao Corporation, Solid content: 25% | | |
| by mass) | | |
| Distilled water | 46.6% | by mass |

—Preparation of an Application Liquid for a White Pigment Layer—

Components in the compositions described below were mixed to prepare an application liquid for a white pigment layer.

### <Composition of an Application Liquid for a White Pigment Layer>

| | | |
|---|---|---|
| Pigment dispersion described above | 70.9% | by mass |
| Polyolefin resin aqueous dispersion | 19.2% | by mass |
| (Binder: ARROW BASE (registered trademark) SE-1010, manufactured by UNITIKA LTD., | | |
| Solid content: 20% by mass) | | |
| Polyoxyalkylene alkyl ether | 3.0% | by mass |
| (NAROACTY (registered trademark) CL95, manufactured by Sanyo Chemical Industries, | | |
| Ltd., Solid content: 1% by mass) | | |
| Oxazoline compound | 6.9% | by mass |
| (EPOCROS (registered trademark) WS-700, manufactured by NIPPON SHOKUBAI CO., | | |
| LTD., Solid content: 25% by mass, a crosslinking agent) | | |

<Production of a Backsheet>

The application liquid for the undercoat layer described above was coated on the side opposite to the side provided with the first and second polymer layer of the polymer sheet which was produced as described in Example 1. Afterward, by drying at 180° C. for 1 minute, an undercoat layer (thickness: 0.1 μm) in which the coating quantity was 0.1 g/m² was formed.

In addition, on the dried undercoat layer, the application liquid for the white pigment layer was applied so that an amount of titanium dioxide become 8.5 g/m², and a coating film was dried at 180° C. for 1 minute, to form a white pigment layer (a reflecting layer) (thickness: 10 μm).

As described above, a backsheet for a solar cell using the polymer sheet obtained in Example 1 was produced.

—Production of a Solar Cell Module—

A tempered glass having a thickness of 3 mm, a first EVA sheet (trade name: SC50B, manufactured by Mitsui Chemicals Fabra Inc.), a crystalline solar cell, a second EVA sheet (trade name: SC50B, manufactured by Mitsui Chemicals Fabra Inc.) and the backsheet of Example 1 were layered in this order and subjected to hot pressing by using a vacuum laminator (manufactured by Nisshinbo Chemical Inc., a vacuum layering machine). The tempered glass, the first EVA sheet, the crystalline solar cell, the second EVA sheet, and the backsheet were thus adhered. At this time, the backsheet produced as described above was disposed so that the side on which the white pigment layer (the reflecting layer) thereof was formed contacts the second EVA sheet. The method of adhering was as follows.

After evacuating at 128° C. for 3 minutes by using the vacuum laminator, pressure was applied for 2 minutes for temporal adhering. Afterward, adhesion treatment was conducted at 150° C. for 30 minutes using a dry oven.

A crystalline solar cell module was produced in this manner. When the produced solar cell module was executed to generate electricity, excellent power generation performance as a solar cell was exhibited.

### Examples 24 to 44

Each backsheet was produced by the same as Example 23 using the polymer sheets produced in Examples 2 to 22, and solar cell modules in Examples 24 to 44 were produced using the backsheets.

When generating operation was executed by using the produced solar cell module, all exhibited excellent power generation performance as a solar cell.

The entire disclosure of Japanese Patent Application No. 2011-155781 is incorporated by reference in this specification.

All literatures, patents, patent applications and engineering standards described in this specification are incorporated by reference in this specification to the same degree as a case of specifically and respectively describing that respective literature, patent, patent application and engineering standard are incorporated by reference.

What is claimed is:

1. A polymer sheet for a solar cell, comprising:
a first polymer layer;
a second polymer layer; and
a polymer support, arranged in this order,
wherein the first polymer layer comprises a polymer selected from the group consisting of a fluorine polymer and a silicone polymer,
the first polymer layer contacts the second polymer layer, and
a roughness (Rz) of an interface between the first polymer layer and the second polymer layer is in a range of from 0.2 μm to 3.0 μm.

2. The polymer sheet according to claim 1, wherein the second polymer layer comprises a silicone polymer.

3. The polymer sheet according to claim 1, wherein the second polymer layer comprises particles having a volume average particle diameter in a range of from 0.2 μm to 1.5 μm.

4. The polymer sheet according claim 1, wherein the second polymer layer comprises particles having a volume average particle diameter in a range of from 0.3 μm to 0.6 μm.

5. The polymer sheet according to claim 1, wherein the second polymer layer comprises titanium dioxide particles.

6. The polymer sheet according to claim 1, wherein the first polymer layer and the second polymer layer are layers formed by coating.

7. The polymer sheet according to claim 1, wherein the first polymer layer is an outermost layer.

8. The polymer sheet according to claim 1, wherein:
the second polymer layer comprises a silicone polymer;
the second polymer layer comprises particles which are selected from the group consisting of titanium dioxide particles and polymethylmethacrylate resin particles and which have a volume average particle diameter in a range of from 0.2 μm to 1.5 μm;
the first polymer layer and the second polymer layer are layers formed by coating; and
the first polymer layer is an outermost layer.

9. The polymer sheet according to claim 1, wherein the polymer support comprises a terminal sealing agent in an amount of from 0.1% by mass to 10% by mass with respect to a total mass of the polymer that configures the polymer support.

10. The polymer sheet according to claim 1, wherein:
the second polymer layer comprises a silicone polymer;
the second polymer layer comprises titanium dioxide particles having a volume average particle diameter in a range of from 0.3 μm to 0.6 μm;
the first polymer layer and the second polymer layer are layers formed by coating;
the first polymer layer is an outermost layer; and
the polymer support comprises a terminal sealing agent in an amount of from 0.1% by mass to 10% by mass with respect to a total mass of the polymer that configures the polymer support.

11. The polymer sheet according to claim 1, wherein
the polymer support comprises fine particles that are inorganic particles or organic particles,
an average particle diameter of the fine particles is from 0.1 μm to 10 μm, and
a content of the fine particles is less than or equal to 50% by mass with respect to a total mass of the polymer support.

12. The polymer sheet according to claim 1, wherein:
the second polymer layer comprises a silicone polymer;
the second polymer layer comprises titanium dioxide particles having a volume average particle diameter in a range of from 0.3 μm to 0.6 μm;
the first polymer layer and the second polymer layer are layers formed by coating;
the first polymer layer is an outermost layer; and
the polymer support comprises fine particles that are inorganic particles or organic particles, an average particle diameter of the fine particles is from 0.1 μm to 10 μm, and a content of the fine particles is less than or equal to 50% by mass with respect to a total mass of the polymer support.

13. A method of manufacturing the polymer sheet according to claim 1, comprising:
forming a polymer support and an undercoat layer, including:
supplying an unstretched sheet that comprises a polymer that configures the polymer support,
stretching the unstretched sheet in a first direction,
applying a composition for forming an undercoat layer onto at least one surface of the sheet stretched in the first direction, and
stretching the sheet, to which the composition for forming an undercoat layer is applied, in a direction perpendicular to the first direction; and
disposing the second polymer layer and the first polymer layer, in this order, on the undercoat layer.

14. A method of manufacturing the polymer sheet according to claim 1, comprising treating a surface of the polymer support by a method selected from the group consisting of corona treatment, flame treatment and glow discharge treatment.

15. A solar cell module comprising;
a front substrate on which sunlight is incident and which has transparency;
a cell structure part that is provided on one surface of the front substrate and includes a solar cell element and a sealant that seals the solar cell element; and
a backsheet provided on an opposite side to a side at which the front substrate of the cell structure part is located, is disposed so as to contact the sealant, and is the polymer sheet according to claim 1.
